(19) United States
(12) Patent Application Publication
(10) Pub. No.: US 2017/0069832 A1
(43) Pub. Date: Mar. 9, 2017

(54) MAGNETORESISTIVE MEMORY DEVICES AND METHODS OF MANUFACTURING THE SAME

(71) Applicants: Yong-Jae KIM, Seoul (KR); Woo-Jin KIM, Guri-si (KR); Ki-Seok SUH, Hwaseong-si (KR); Shin-Hee HAN, Seongnam-si (KR); Gwan-Hyeob KOH, Seoul (KR)

(72) Inventors: Yong-Jae KIM, Seoul (KR); Woo-Jin KIM, Guri-si (KR); Ki-Seok SUH, Hwaseong-si (KR); Shin-Hee HAN, Seongnam-si (KR); Gwan-Hyeob KOH, Seoul (KR)

(21) Appl. No.: 15/186,420

(22) Filed: Jun. 17, 2016

(30) Foreign Application Priority Data
Sep. 3, 2015 (KR) 10-2015-0124589
Oct. 16, 2015 (KR) 10-2015-0144644

(51) Int. Cl. H01L 43/08; H01L 43/10; H01L 43/02; H01L 27/22

(52) U.S. Cl. CPC H01L 43/08; H01L 27/228; H01L 43/10; H01L 43/02

(57) ABSTRACT

A magnetoresistive memory device includes a lower electrode on a substrate, a magnetic tunnel junction (MTJ) structure on the lower electrode, and a mask structure. The MTJ structure includes a lower magnetic pattern, a tunnel barrier pattern, and an upper magnetic pattern which are stacked. The mask structure includes an upper electrode and a sidewall capping pattern enclosing a sidewall of the upper electrode.

### CROSS-REFERENCE TO RELATED APPLICATIONS

This application claims priority under 35 U.S.C. §119 to Korean Patent Application No. 10-2015-0124589 filed on Sep. 3, 2015, and Korean Patent Application No. 10-2015-0144644 filed on Oct. 16, 2015, the entire contents of both are hereby incorporated by reference.

### BACKGROUND

Example embodiments of the inventive concepts relate to semiconductor devices and methods of manufacturing the same, more particularly, to magnetoresistive memory devices and methods for manufacturing the same.

A magnetoresistive memory device includes a memory cell having a magnetic resistive structure. The magnetic resistive structure includes a lower electrode, a magnetic tunnel junction (MTJ), and an upper electrode that are sequentially stacked. When the MTJ is patterned, materials constituting the MTJ are not easily etched.

### SUMMARY

According to example embodiments of the inventive concepts, a magnetoresistive memory device may include a lower electrode on a substrate, a magnetic tunnel junction (MTJ) structure on the lower electrode and a mask structure on the MTJ structure, the mask structure including an upper electrode and a sidewall capping pattern surrounding a sidewall of the upper electrode.

According to example embodiments of the inventive concepts, a magnetoresistive memory device may include an interlayer insulating layer including a conductive pattern therein on a substrate; a lower electrode on an interlayer insulating layer and contacting the conductive pattern; a MTJ structure on the lower electrode, a mask structure on the MTJ structure and including an upper electrode and a sidewall capping pattern surrounding a sidewall of the upper electrode; and an interconnection layer electrically connected to the upper electrode.

According to example embodiments of the inventive concept, a method of manufacturing a magnetoresistive memory device may include sequentially forming a lower electrode layer and a magnetic tunnel junction (MTJ) layer on a substrate in which the MTJ layer may include a lower magnetic layer, a tunnel barrier layer and an upper magnetic layer; forming an etch mask on the MTJ layer in which the etch mask may include a preliminary upper electrode and a preliminary sidewall capping pattern on a sidewall of the preliminary upper electrode; and anisotropically etching the MTJ layer and the lower electrode layer using the etch mask to form a lower electrode, a MTJ structure, an upper electrode, and a sidewall capping pattern in which the MTJ structure may include a lower magnetic pattern, a tunnel barrier pattern and an upper magnetic pattern.

According to example embodiments of the inventive concepts, a method of manufacturing a magnetoresistive memory device may include sequentially forming a lower electrode layer, an MTJ layer and a mold layer on a substrate; etching a portion of the mold layer to form a mold pattern including a hole that exposes a portion of the MTJ layer; forming a preliminary sidewall capping pattern on an inner sidewall of the hole; forming a preliminary upper electrode on the preliminary sidewall capping pattern and the MTJ layer to fill the hole; removing the mold pattern; and anisotropically etching the MTJ layer and the lower electrode layer using the preliminary upper electrode and the preliminary sidewall capping pattern as an etch mask to form a lower electrode, a MTJ structure, an upper electrode and a sidewall capping pattern.

According to example embodiments of the inventive concepts, a method of manufacturing a magnetoresistive memory device may include forming an interlayer insulating layer including a conductive pattern therein on a substrate and forming a lower electrode layer and an MTJ layer that are sequentially stacked on the interlayer insulating layer in which the MTJ layer includes a lower magnetic layer, a tunnel barrier layer and an upper magnetic layer that are stacked; forming an etch mask including a preliminary upper electrode and a preliminary sidewall capping pattern on a sidewall of the preliminary upper electrode; anisotropically etching the MTJ layer and the lower electrode layer using the etch mask to form a lower electrode contacting the conductive pattern, an MTJ structure on the electrode and a mask structure on the MTJ structure in which the MTJ structure includes a lower magnetic pattern, a tunnel barrier pattern and an upper magnetic layer that are stacked, and the mask structure includes an upper electrode and a sidewall capping pattern; and forming an interconnection layer electrically connected to the upper electrode.

According to example embodiments, a magnetoresistive memory comprises an array of lower electrodes on a substrate; and a plurality of magnetoresistive memory cells in which each magnetoresistive memory cell is arranged on a corresponding lower electrode, and at least one magnetoresistive memory cell comprises a mask structure that includes an upper electrode of the magnetoresistive memory cell and a sidewall capping pattern on a sidewall of the upper electrode. The magnetoresistive memory cell may further comprise a first magnetic layer, a tunnel barrier layer and a second magnetic layer that are sequentially stacked in which the stack of the first magnetic layer, the tunnel barrier layer and the second magnetic layer comprise a width in a direction that is substantially perpendicular to a direction of the sequential stack, and a width of the mask structure is substantially equal to the width of the sequential stack.

According to example embodiments, a method of forming magnetoresistive memory comprises forming an array of lower electrodes on a substrate; forming a plurality of magnetoresistive memory cells, each magnetoresistive memory cell being arranged on a corresponding lower electrode; and forming a mask structure on at least one magnetoresistive memory cell in which the mask structure includes an upper electrode of the magnetoresistive memory cell and a sidewall capping pattern on a sidewall of the upper electrode. Forming the at least one magnetoresistive memory cell may comprise forming a first magnetic layer; forming a tunnel barrier layer on the first magnetic layer; and forming a second magnetic layer on the tunnel barrier layer, in which the magnetoresistive memory cell comprises a width in a direction that is substantially perpendicular to a direction of the sequential stack, and a width of the mask structure is substantially equal to the width of the magnetoresistive memory cell.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIGS. 1A and 1B respectively are a sectional view and a perspective view depicting a magnetoresistive memory device according to example embodiments of the inventive concepts.

FIG. 1C is another sectional view depicting a magnetoresistive memory device according to example embodiments of the inventive concepts.

FIGS. 2 through 4, 6 through 10, and 12 are sectional views depicting stages of a method of manufacturing a magnetoresistive memory device according to example embodiments of the inventive concepts.

FIGS. 5 and 11 are plan views depicting stages of a method of manufacturing a magnetoresistive memory device according to example embodiments of the inventive concepts.

FIGS. 13 through 18 are sectional views depicting stages of a method of manufacturing a magnetoresistive memory device according to example embodiments of the inventive concepts.

FIG. 19 is a sectional view depicting a magnetoresistive memory device according to example embodiments of the inventive concepts.

FIG. 20 is a sectional view depicting a magnetoresistive memory device according to example embodiments of the inventive concepts.

FIGS. 21A and 21B are conceptual diagrams depicting magnetic tunnel junction patterns according to some embodiments of the inventive concepts.

FIG. 22 is a sectional view depicting a magnetoresistive memory device according to example embodiments of the inventive concepts.

FIGS. 23 through 29 are sectional views depicting stages of a method of manufacturing a magnetoresistive memory device according to example embodiments of the inventive concepts.

FIG. 30 is a flow diagram of a method of manufacturing a magnetoresistive memory device corresponding to FIGS. 2 through 12 according to example embodiments of the inventive concepts.

FIG. 31 depicts an electronic device that comprises one or more integrated circuits (chips) comprising a semiconductor device that includes a magnetoresistive memory device according to embodiments disclosed herein.

### DETAILED DESCRIPTION

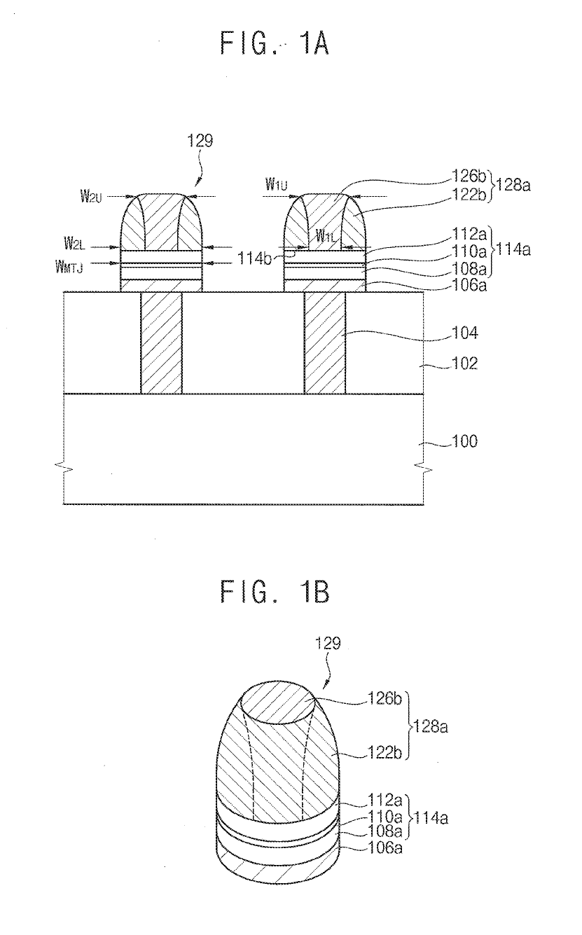

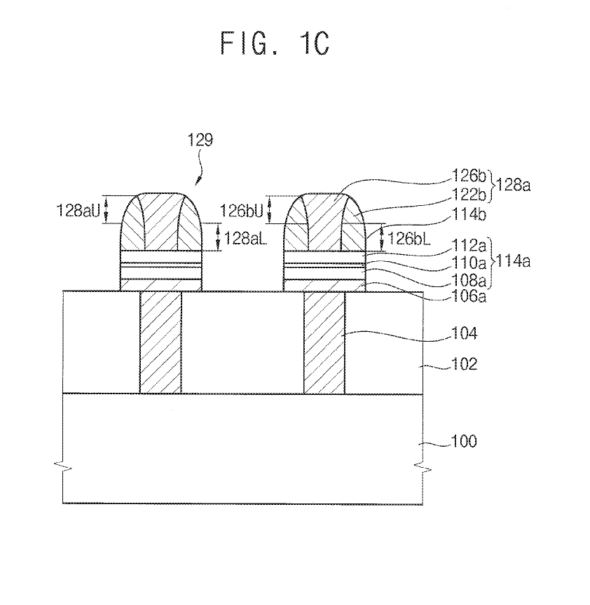

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein. FIGS. 1A and 1C are sectional views depicting a magnetoresistive memory device according to example embodiments of the inventive concepts. FIG. 1B is a perspective view depicting a magnetoresistive memory device according to example embodiments of the inventive concepts.

Referring to FIGS. 1A and 1B, a magnetoresistive memory device may include an interlayer insulating layer 102 and a contact plug 104 on the substrate 100. The contact plug 104 may pass through the interlayer insulating layer 102 to be in contact with the substrate 100. The magnetoresistive memory device may include a variable-resistance structure 129 on the interlayer insulating layer 102. The variable-resistance structure 129 may be in contact with a top surface of the contact plug 104. The variable-resistance structure 129 may include a lower electrode 106a, a magnetic tunnel junction (MTJ) structure 114a, an upper electrode 126b and a sidewall capping pattern 122b.

The substrate 100 may include silicon, germanium, silicon-germanium or a III-V group semiconductor compound, such as GaP, GaAs or GaSb. In some example embodiments, the substrate may include a silicon-on-insulator (SOI) substrate or a germanium-on-insulator (GOI) substrate.

Although not depicted in drawings, a variety of elements, such as, but not limited to, a transistor, a diode, source/drain regions, a source line and/or a word line, may be formed on the substrate 100.

The contact plug 104 may include, for example, a metal, such as tungsten, titanium or tantalum, a metal nitride, such as tungsten nitride, titanium nitride or tantalum nitride, and/or doped polysilicon.

The lower electrode 106a may cover the entire top surface of the contact plug 104 and have a bottom surface that is larger than the top surface of the contact plug 104.

The lower electrode 106a may be formed of a metal and/or a metal nitride. For example, the lower electrode 106a may include a metal, such as tungsten, titanium or tantalum, and/or a metal nitride, such as tungsten nitride, titanium nitride or tantalum nitride. In some example embodiments, a barrier metal layer may further be formed on the lower electrode 106a. The lower electrode 106a may be formed from multiple layers.

Alternatively, the lower electrode 106a may be formed from a single layer.

The MTJ structure 114a may include a first magnetic pattern 108a, a tunnel barrier pattern 110a and a second magnetic pattern 112b that are sequentially stacked on the lower electrode 106a.

The MTJ structure 114a may be disposed on the lower electrode 106a and may cover an entire top surface of the lower electrode 106a. The MTJ structure 114a may include a bottom surface having substantially the same area as the area of the top surface of the lower electrode 106a.

In some example embodiments, a stack structure including the lower electrode 106a and the MTJ structure 114a may have a substantially vertical sidewall. In other example embodiments, the stack structure including the lower electrode 106a and the MTJ structure 114a may have an inclined sidewall. For example, the stack structure may have a cross section having a trapezoidal shape.

In some example embodiments, the first magnetic pattern 108a may function as a pinning magnetic layer structure that is configured to have a fixed magnetization direction.

In some example embodiments, the first magnetic pattern 108a may include a pinning magnetic pattern, a lower ferromagnetic pattern, an anti-ferromagnetic pattern, an anti-ferromagnetic coupling spacer pattern and an upper ferromagnetic pattern. The pinning magnetic pattern may include, for example, FeMn, IrMn, PtMn, MnO, MnS, MnTe, MnF₂, FeF₂, FeCl₂, FeO, CoCl₂, CoO, NiCl₂, NiO and/or Cr. The lower and upper ferromagnetic patterns may include a ferromagnetic material, for example, Fe, Ni and/or Co. The anti-ferromagnetic coupling spacer pattern may include, for example, Ru, Ir and/or Rh.

The second magnetic pattern 112a may function as a free magnetic layer that is configured to have a varying magnetization direction. In this case, the second magnetic pattern 112a may include a ferromagnetic material, such as Fe, Co, Ni, Cr and/or Pt. The second magnetic pattern 112a may further include B or Si. The second magnetic pattern 112a may include a single ferromagnetic material or a combination of two or more ferromagnetic materials, for example, CoFe, NiFe, FeCr, CoFeNi, PtCr, CoCrPt, CoFeB, NiFeSiB and/or CoFeSiB.

The tunnel barrier pattern 110a may be interposed between the first magnetic pattern 108a and the second magnetic pattern 112a. Thus, the first magnetic pattern 108a and the second magnetic pattern 112a may not be in direct contact with each other.

The tunnel barrier pattern 110a may include an insulating metal oxide. For example, the tunnel barrier pattern 110a may include magnesium oxide (MnOx) and/or aluminum oxide (AlOx).

As described above, the free magnetic layer of the MTJ structure 114a may be disposed above the pinning magnetic layer structure. However, in some example embodiments, the free magnetic layer of the MTJ structure 114a may be disposed under the pinning magnetic layer structure.

The upper electrode 126b may be disposed on the central portion of a top surface of the MTJ structure 114a to at least partially cover the top surface of the MTJ 114a.

The upper electrode 126b may have a lower width W_{1L} and an upper width W_{1U} that is larger than the lower width W_{1L}. In one example embodiment, the lower width W_{1L} has a range from about 20 nm to about 30 nm. In one example embodiment, the upper width Wᵢᵤ has a range from about 25 nm to about 35 nm. A maximum width of the upper electrode 126b may be the same as or less than a width W_{MTJ} of an upper portion of the MTJ structure 114a.

In some example embodiments, the upper electrode 126b may include a lower portion 126bL having a constant or substantially constant width and an upper portion 126bU having a width that is larger than the width of the lower portion 126bL, as shown in FIG. 1C. It should be understood that while the lower portion 126bL and the upper portion 126bU of the upper electrode 126b are indicated in FIG. 1C, the indicated demarcations are only generally located and could vary depending on the particular example embodiment. The width of the upper portion 126bU of the upper electrode 126b may gradually increase as the distance increases from the substrate 100.

In other example embodiments, the upper electrode 126b may have a width that gradually increases as a distance increases from a bottom surface to a top surface of the upper electrode 126b.

The upper electrode 126b may act as a part of a hard mask in an etching process that forms the MTJ structure 114a and the lower electrode 106a.

The upper electrode 126b may be formed of a metal and/or a metal nitride. For example, the upper electrode 126b may include a metal, such as tungsten, titanium, tantalum or iron, and/or a metal nitride, such as tungsten nitride, titanium nitride or tantalum nitride. In some example embodiments, the upper electrode 126b may include tungsten.

The sidewall capping pattern 122b may be disposed on the MTJ structure 114a to surround a sidewall of the upper electrode 126b. The sidewall capping pattern 122b may cover an edge portion 114b of the MTJ structure 114a.

The sidewall capping pattern 122b may serve as a part of a hard mask during an etching process that forms the MTJ structure 114a and the lower electrode 106a. The sidewall capping pattern 122b may include an insulating material. For example, the sidewall capping pattern 122b may include silicon nitride, silicon oxynitride and/or silicon oxide.

A mask structure 128a that includes the upper electrode 126b and the sidewall capping pattern 122b may cover the top surface of the MTJ structure 114a. The mask structure 128a may include a bottom surface that has substantially the same area as the area of the top surface of the MTJ structure 114a.

A lower width W_{2L} of the mask structure 128a may be larger than an upper width W_{2U} of the mask structure 128a. In one example embodiment, the lower width W_{2L} of the mask structure 128a has a range from about 45 nm to about 55 nm. In one example embodiment, the upper width W_{2U} of the mask structure 128a has a range from about 25 nm to about 40 nm.

In some example embodiments, the mask structure 128a may include a lower portion 128aL having a constant or substantially constant width and an upper portion 128aU having a width that is less than the width of the lower portion 128aL, as shown in FIG. 1C. It should be understood that while the lower portion 128aL and the upper portion 128aU of the mask structure 128a are indicated in FIG. 1C, the indicated demarcations are only generally located and could vary depending on the particular example embodiment. The width of the upper portion 128aU of the mask structure 128a may gradually decrease as the distance increases from the substrate 100.

In other example embodiments, the mask structure 128a may have a width that gradually decreases as a distance increases from a bottom surface to a top surface of the mask structure 128a.

On the top surface of the mask structure 128a, an exposed area of the upper electrode 126b may be larger than that of the sidewall capping pattern 122b. That is, an exposed area of the top surface of the mask structure 128a as viewed in a plan view may be larger than a projected area of the sidewall capping pattern 122b as viewed in the plan view. In some example embodiments, the top surface of the upper electrode 126b, which may correspond to the top surface of the mask structure 128a, may be exposed, and a side surface of the sidewall capping pattern 122b, which may correspond to a sidewall of the mask structure 128a, may also be exposed.

The MTJ structure 114a and the lower electrode 106a may be formed using the mask structure 128a as an etch mask. Since the upper electrode 126b is not exposed at the sidewall of the mask structure 128a, an exposed area of the upper electrode 126b may be reduced. Therefore, during the etching process for forming the MTJ structure 114a and the lower electrode 106a using the mask structure, formation of conductive etch by-products from the upper electrode 126b may be prevented or reduced, thereby preventing a short circuit from being formed between the first and second magnetic patterns 108a and 112a by the conductive etch by-products being re-deposited on a sidewall of the patterned MTJ structure 114a and the lower electrode 106a.

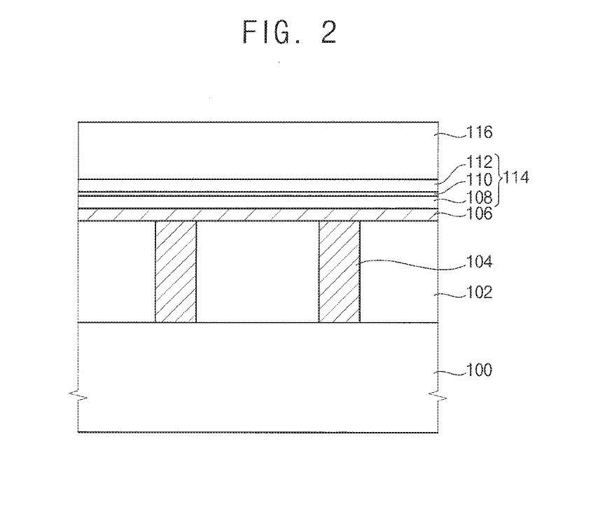

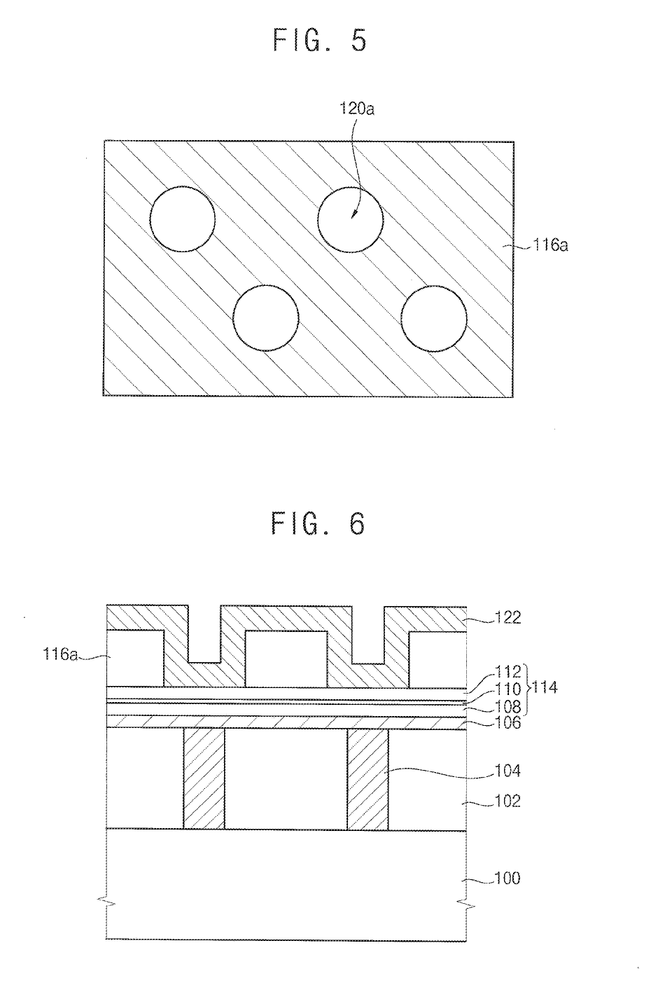

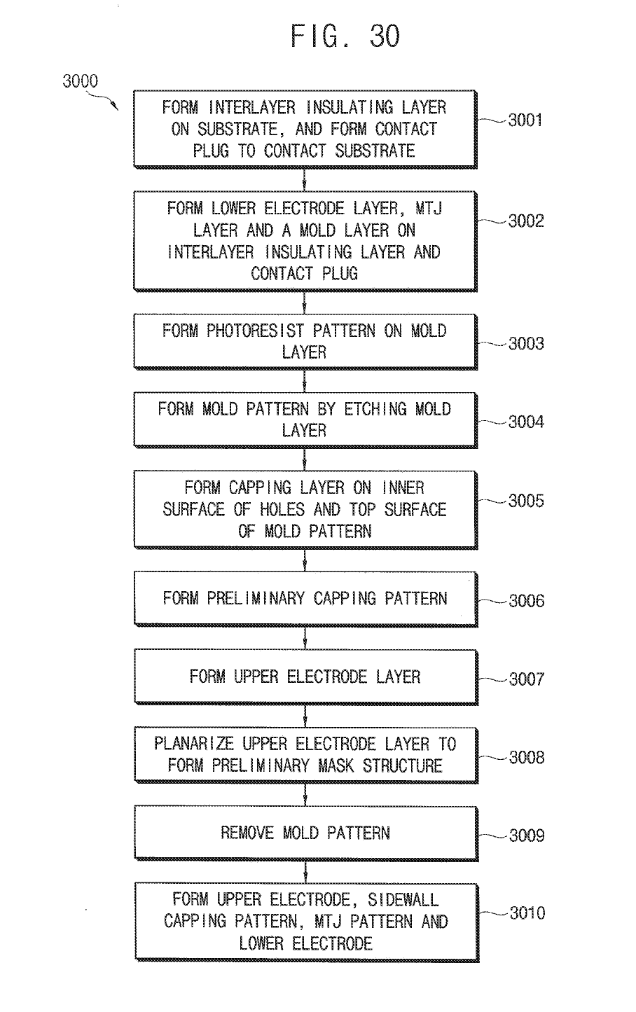

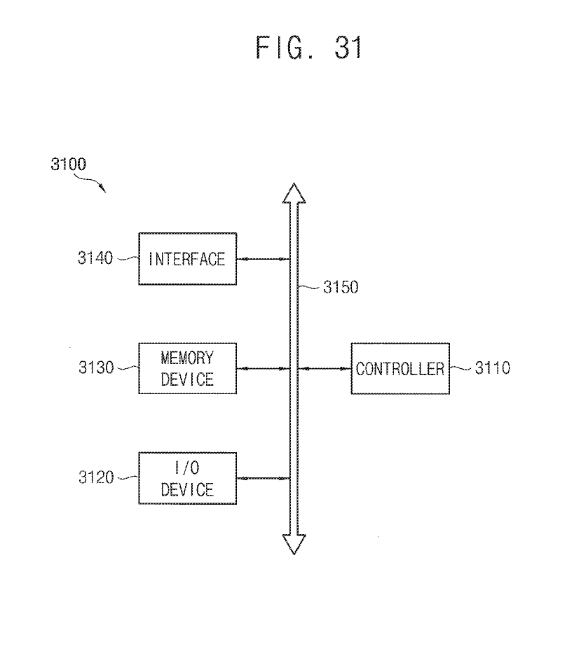

FIGS. 2 through 4, 6 through 10, and 12 are sectional views depicting stages of a method of manufacturing a magnetoresistive memory device according to example embodiments of the inventive concepts. FIGS. 5 and 11 are plan views depicting stages of a method of manufacturing a magnetoresistive memory device according to example embodiments of the inventive concepts. FIG. 30 is a flow diagram of a method of manufacturing a magnetoresistive memory device corresponding to FIGS. 2 through 12 according to example embodiments of the inventive concepts.

Referring to FIG. 2 and operation 3001 in FIG. 30, an interlayer insulating layer 102 may be formed in a well-known manner on a substrate 100, and a contact plug 104 may be formed in a well-known manner to electrically contact the substrate 100 by passing through the interlayer insulating layer 102.

The interlayer insulating layer 102 may be formed of, for example, an oxide, such as silicon oxide. The interlayer insulating layer 102 may be formed using a chemical vapor deposition (CVD) process, an atomic layer deposition (ALD) process or a spin coating process.

The formation of the contact plug 104 may include forming a contact hole that passes through the interlayer insulating layer 102 to expose a top surface of the substrate 100, forming a conductive layer on the substrate 100 and the interlayer insulating layer 102 to fill the contact hole, and planarizing the conductive layer until a top surface of the interlayer insulating layer 103 is exposed.

Referring to again to FIG. 2 and to operation 3002 in FIG. 30, a lower electrode layer 106, a MTJ layer 114 and a mold layer 116 may be sequentially formed in a well-known manner on the interlayer insulating layer 102 and the contact plug 104.

The lower electrode layer 106 may be formed of a metal and/or a metal nitride.

The MTJ layer 114 may include a first magnetic layer 108, a tunnel barrier layer 110, and a second magnetic layer that are sequentially stacked.

The first magnetic layer 108 may include a pinning magnetic layer, a lower ferromagnetic pattern, an anti-ferromagnetic layer, an anti-ferromagnetic coupling spacer layer, and an upper ferromagnetic layer. The pinning layer may include, for example, FeMn, IrMn, PtMn, MnO, MnS, MnTe, MnF₂, FeF₂, FeCl₂, FeO, CoCl₂, CoO, NiCl₂, NiO and/or Cr. The lower and upper ferromagnetic layers may include a ferromagnetic material, for example, Fe, Ni and/or Co. The anti-ferromagnetic coupling spacer layer may include, for example, Ru, Ir and/or Rh. The tunnel barrier pattern 110a may include, for example, magnesium oxide (MnOx) and/or aluminum oxide (AlOx).

The second magnetic layer 112 may function as a free magnetic layer. The second magnetic layer 112 may include a ferromagnetic material, for example, Fe, Co, Ni, Cr and/or Pt. The second magnetic layer 112 may further include B or Si. The second magnetic layer 112 may include a single ferromagnetic material or a combination of two or more ferromagnetic materials, for example, CoFe, NiFe, FeCr, CoFeNi, PtCr, CoCrPt, CoFeB, NiFeSiB, and/or CoFeSiB.

The mold layer 116 may include a material having an etch selectivity with respect to an upper electrode and a sidewall capping layer that are to be formed in the following process. Additionally, the mold layer 116 may include a material that can be easily etched by an isotropic-etching process. The mold layer 116 may include silicon oxide. In some example embodiments, the mold layer 116 may include silicon nitride or silicon oxynitride. The mold layer 116 may be formed using a CVD process or an ALD process.

The mold layer 116 may act as a mold pattern for forming the upper electrode. The mold layer 116 may be formed to have a thickness that is substantially equal to or greater than a target height of the upper surface of the upper electrode.

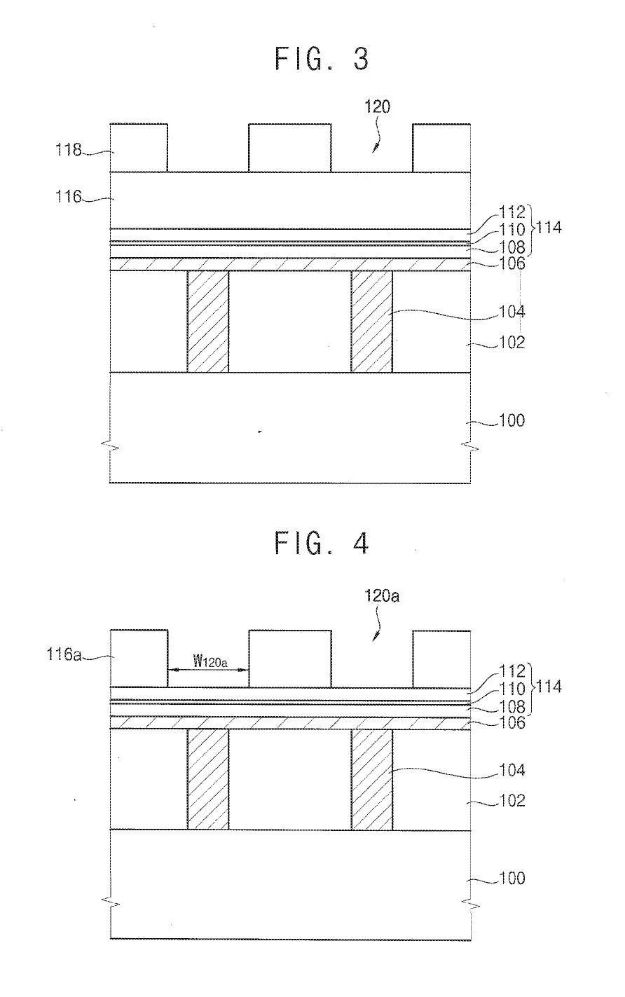

Referring to FIG. 3 and operation 3003 in FIG. 30, a photoresist pattern 118 may be formed on the mold layer 116.

The photoresist pattern 118 may be formed in a well-known manner by coating a photoresist layer on the mold layer 106 and patterning the photoresist layer using an exposing process and a developing process. The photoresist pattern 118 may include an opening 120 that is formed in the photoresist pattern 118. A plurality of openings 120 may be formed in the photoresist pattern 118. The opening 120 may expose a region where the upper electrode will be formed. A bottom surface of the opening 120 may overlap a top surface of the contact plug 104.

Referring to FIGS. 4 and 5, and operation 3004 in FIG. 30, a mold pattern 116a may be formed by anisotropically etching the mold layer 116 using the photoresist pattern 118 as an etch mask. Next, the photoresist pattern 118 may be removed.

The mold pattern 116a may include a first hole 120a that is formed in the mold pattern 116a. The first hole 120a may be formed using the photoresist pattern 118 and may be aligned with the opening 120 of the photoresist pattern 118. A plurality of first holes 120a may be formed in the mold pattern 116a. The top surface of the MTJ layer 114 may be exposed by the first hole 120a.

A size of the first hole 120a may be substantially equal to a size of a mask structure that includes the upper electrode and the sidewall capping pattern.

Referring to FIG. 6 and operation 3005 in FIG. 30, a capping layer 122 may be conformally formed in a well-known manner on an inner surface of the first hole 120a and on a top surface of the mold pattern 116a.

The capping layer 122 may include an insulating material. The capping layer 122 may function as a portion of a hard mask during an etching process of the MTJ layer 114. The capping layer 122 may include a material having an etch selectivity with respect to the MTJ layer 114. Further, the capping layer 122 may include a material having an etch selectivity with respect to the mold pattern 116a.

In some example embodiments, in a case in which the mold pattern 116a includes silicon oxide, the capping layer 122 may include silicon nitride and/or silicon oxynitride. In other example embodiments, in a case in which the mold pattern 116a includes silicon nitride or silicon oxynitride, the capping layer 122 may include silicon oxide. The capping layer 122 may be formed using a CVD process or an ALD process.

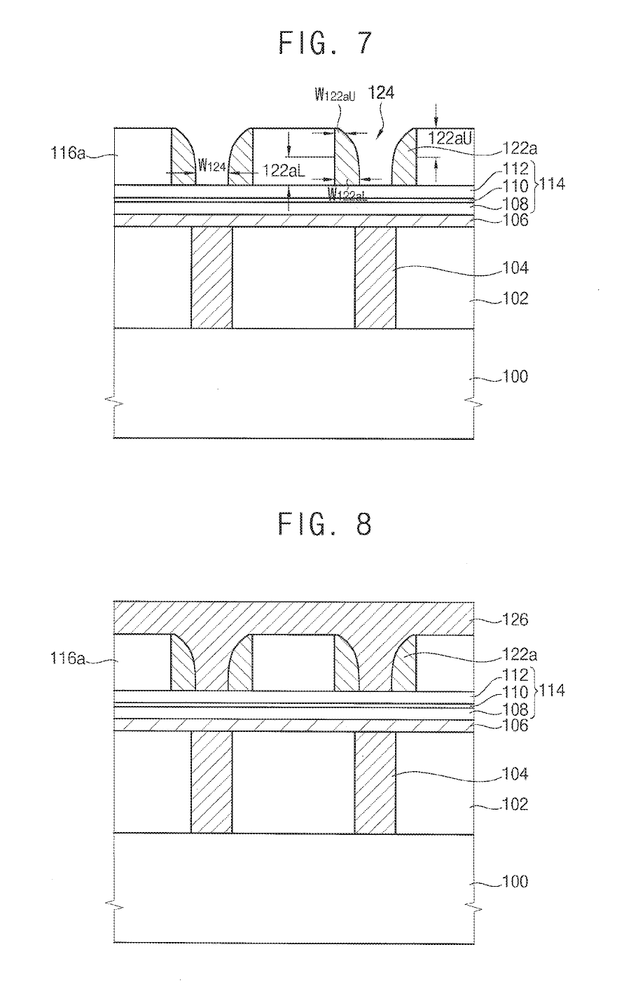

Referring to FIG. 7 and operation 3006 of FIG. 30, a preliminary sidewall capping pattern 122a may be formed on an inner sidewall of the first hole 120a by anisotropically etching the capping layer 122. Thus, a second hole 124 may be formed to have a width W₁₂₄ that is less than the width W₁₂₀ₐ (FIG. 4) of the first hole 120a due to the preliminary sidewall pattern 122a on the sidewalls of the first hole 120a. A plurality of second holes 124 may be formed.

During the anisotropic-etching process, a portion of the capping layer 122 on the top surface of the mold pattern 116a and a bottom surface of the first hole 120a may be etched. Thus, the top surface of the MTJ layer 114 may be exposed by the second hole 124. The preliminary sidewall capping pattern 122a may have an annular shape when viewed in plan view.

During the anisotropic-etching process, a portion of the capping layer 122 on an upper portion of the inner sidewall of the first hole 120a may also be etched. Thus, the preliminary sidewall capping pattern 122a may have a lower width W_{122aL} and an upper width W_{122aU} that is smaller than the lower width W_{122aL}.

In some example embodiments, the preliminary sidewall capping pattern 122a may include a lower portion 122a_{L} having a constant or substantially constant width W_{122aL} and an upper portion 122a_{U} having a width W_{122aU} that is less than the first width. The width of the upper portion of the preliminary sidewall capping pattern 122a may gradually decrease as the distance increases from the substrate 100. It should be understood that while the lower portion 122_{aL} and the upper portion 122_{aU} of the sidewall capping pattern 122a are indicated in FIG. 7, the indicated demarcations are only generally located and could vary depending on the particular example embodiment.

In other example embodiments, the preliminary sidewall capping pattern 122a may have a width that gradually decreases as a distance increases from a bottom surface to a top surface of the preliminary sidewall capping pattern 122a.

Therefore, the second hole 124 may have a lower width and an upper width that is greater than the lower width. In some example embodiments, the second hole 124 may include a lower portion having a constant second width and an upper portion having a width greater than the second width. The width of the upper portion of the second hole 124 may gradually increase as the distance increases from the substrate 100.

In other example embodiments, the second hole 124 may have a width that gradually increases as a distance increases from a bottom portion to a top portion of the second hole 124.

Referring to FIG. 8 and operation 3007 of FIG. 30, an upper electrode layer 126 may be formed in a well-known manner on the top surface of the mold pattern 116a, a surface of the preliminary sidewall capping pattern 122a and the top surface of the MTJ layer 114 to fill the second hole 124.

The upper electrode layer 126 may be provided as a part of a hard mask during an etching process of the MTJ layer 114 and the lower electrode layer 106.

The upper electrode layer 126 may be formed of a metal or a metal nitride. For example, the upper electrode layer 126 may include a metal, such as tungsten, titanium, tantalum or iron, and/or a metal nitride, such as tungsten nitride, titanium nitride or tantalum nitride. In some embodiments, the upper electrode layer 126 may include tungsten.

The upper electrode layer 126 may be formed using a physical vapor deposition process, a chemical vapor deposition process or an atomic layer deposition process.

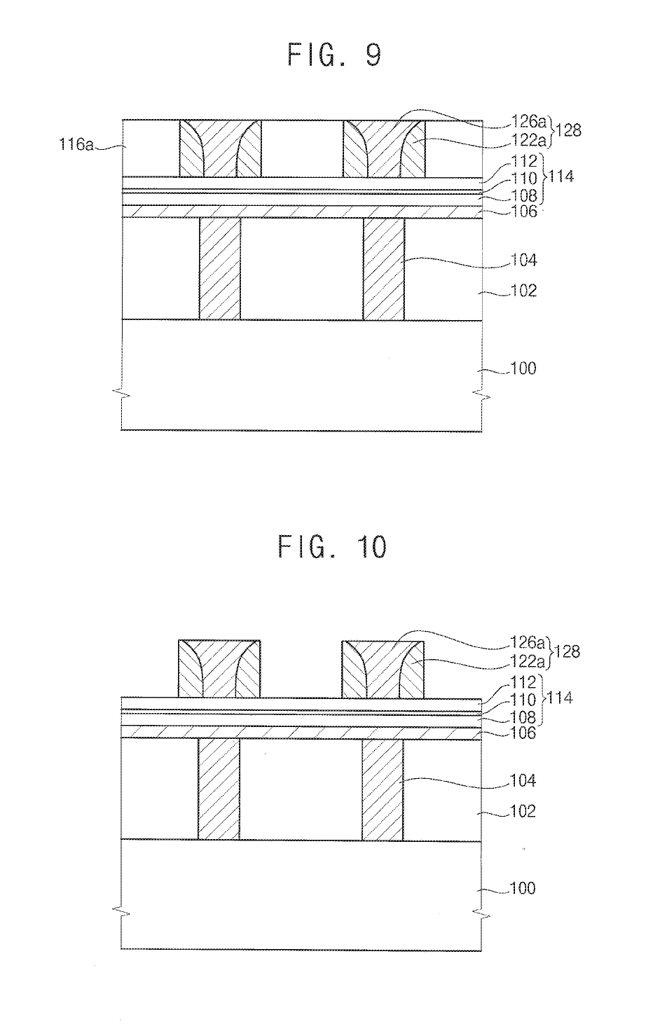

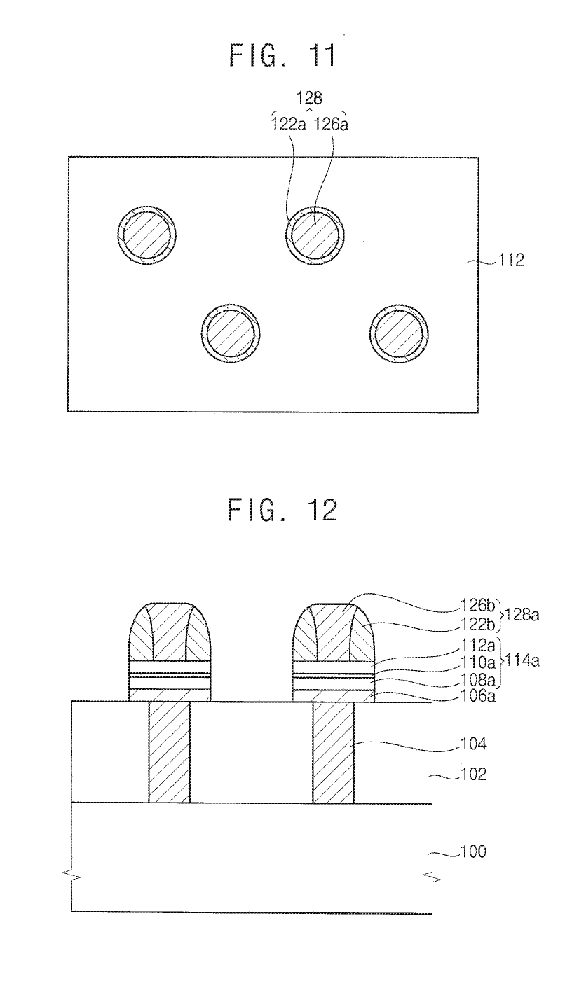

Referring to FIG. 9 and operation 3008 of FIG. 30, the upper electrode layer 126 may be planarized to expose the top surface of the mold pattern 116a, thus forming a preliminary mask structure 128 including a preliminary upper electrode 126a and the preliminary sidewall capping pattern 122a. The planarization process may include a chemical mechanical polishing process and/or an etch-back process. The preliminary mask structure 128 may be directly in contact with the MTJ layer 114.

The preliminary upper electrode 126a may have substantially the same shape as the second hole 124. Thus, the preliminary upper electrode 126a may have a lower width and an upper width that is greater than the lower width (FIG. 1A).

In some example embodiments, the preliminary upper electrode 126a may include a lower portion having the constant or substantially constant width and an upper portion having the width that is greater than the width of the lower portion of the preliminary upper electrode 126a, as also depicted in FIG. 1C. The width of the upper portion of the preliminary upper electrode 126a may gradually increase as the distance increases from the substrate 100. Therefore, the preliminary upper electrode 126a may have a maximum width at an uppermost portion of the preliminary upper electrode 126a.

In other example embodiments, the preliminary upper electrode 126a may have a width that gradually increases in a direction from a bottom surface to a top surface of the preliminary upper electrode 126a.

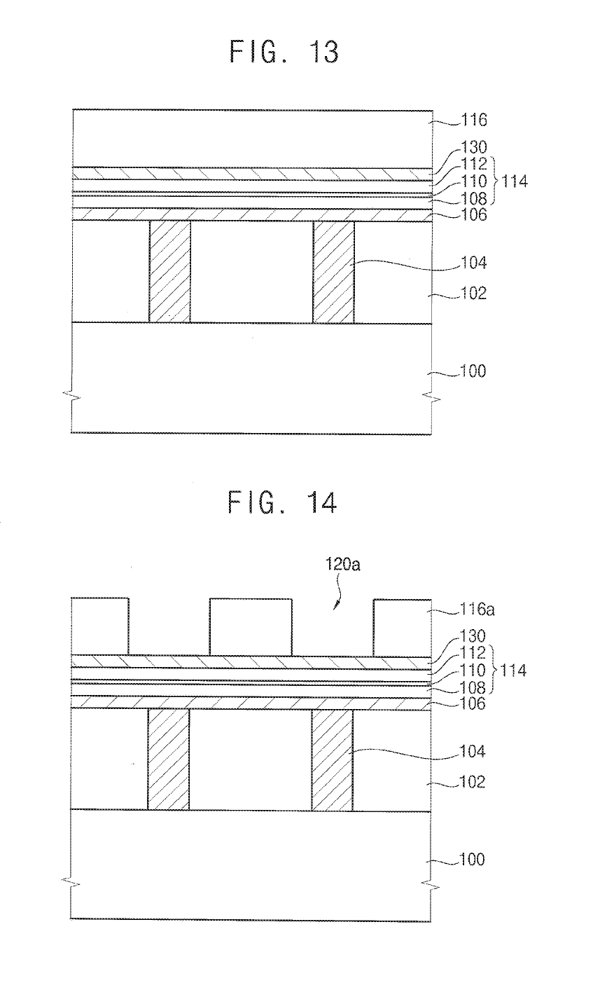

Referring to FIGS. 10 and 11 and operation 3009 in FIG. 30, the mold pattern 116a may be removed using a well-known technique. The mold pattern 116a may be removed by, for example, an isotropic-tech process.

In some example embodiments, in the case in which the mold pattern 116a includes silicon oxide, the mold pattern may 116a may be removed by a wet-etching process using an etchant containing hydrofluoric acid. In other example embodiments, in the case in which the mold pattern 116a includes silicon nitride or silicon oxynitride, the mold pattern may 116a may be removed by a wet-etching process using an etchant containing hydrofluoric acid, phosphoric acid and/or sulfuric acid.

The top surface of MTJ layer 114 on which the preliminary mask structure 128 is not formed may be exposed. The preliminary mask structure 128 may function as a hard mask that is used for etching the MTJ layer 114. As described above, the preliminary mask structure 128 may be formed using a damascene process.

On a top surface of the preliminary mask structure 128, an exposed area of the preliminary upper electrode 126a as viewed in a plan view may be greater than a projected area of the preliminary sidewall capping pattern 122a as viewed in the plan view. Additionally, the preliminary upper electrode 126a may not be exposed at a sidewall of the preliminary mask structure 128.

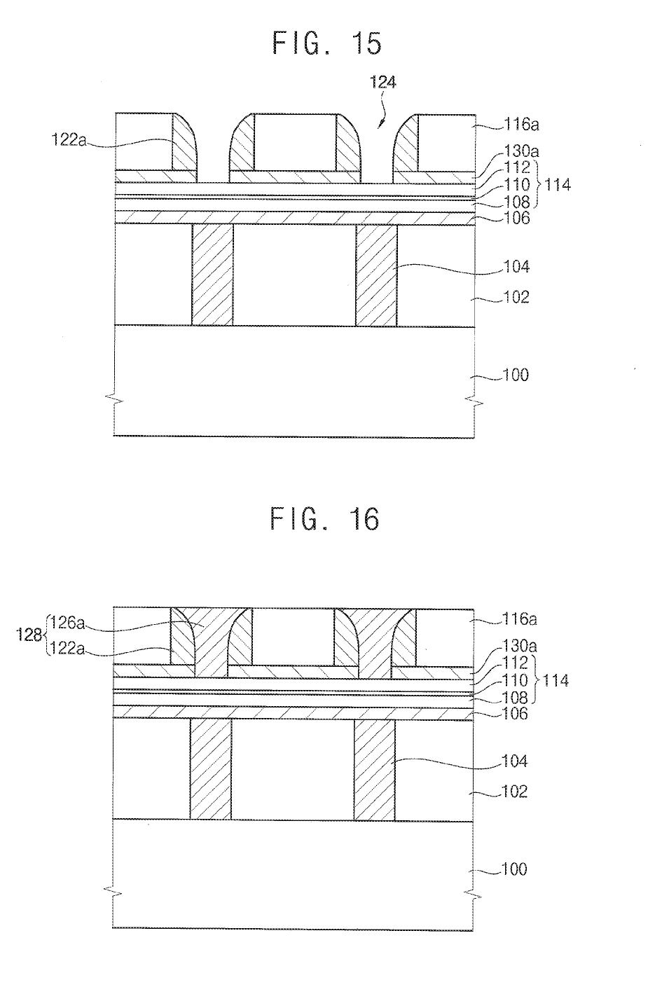

Referring to FIG. 12 and operation 3010 in FIG. 30, the MTJ layer 114 and the lower electrode layer 106 may be sequentially anisotropically etched in a well-known manner using the preliminary mask structure 128 as an etch mask. Thus, a lower electrode 106a that is in contact with the contact plug 104, a MTJ structure 114a, an upper electrode 126b, and a sidewall capping pattern 122b surrounding a sidewall of the upper electrode 126b may be formed. That is, a mask structure 128a that includes the upper electrode 126b and the sidewall capping pattern 122b surrounding the sidewall of the upper electrode 126b may be formed on the MTJ structure 114a.

The anisotropic-etching process may include a dry-etching process, such as an ion-beam etching process, a sputter-etching process or a radio-frequency (RF) etching process. In some example embodiments, the MTJ layer 114 and the lower electrode layer 106 may be effectively etched using the ion-beam etching process.

An ion-beam etching process is performed so that electrically-accelerated ions collide with an etch-target layer, and surface atoms of the etch-target layer may be etched by the collision of the accelerated ions. Thus, during an ion-beam etching process, a portion of an upper sidewall of the preliminary sidewall capping pattern 122a may be etched due to the collision of ions. Meanwhile, because the preliminary upper electrode 126a is exposed at the top surface of the preliminary mask structure 128 as compared to the preliminary sidewall capping pattern 122a, and the upper width is less than the lower width of the preliminary sidewall capping pattern 122a, the accelerated ions may mostly collide with the preliminary upper electrode 126a having the substantially larger exposed area. The preliminary upper electrode 126a has hardness greater than that of the preliminary sidewall capping pattern 122a. Thus, the preliminary sidewall capping pattern 122a may not be removed extensively, may not be damaged, or may not be collapsed by the collision of ions. As a result, the etch-target layer (e.g., the MTJ layer 114 or the lower electrode layer 106) may be effectively etched using the preliminary mask structure 128 as an etch mask.

During the anisotropic-etching process, first etch by-products generated from the etched preliminary sidewall capping pattern 122a may be re-deposited on a sidewall of an etched portion of the MTJ layer 114. However, because the preliminary sidewall capping pattern 122a is formed of an insulating material, an electrical failure (e.g., an electrical short-circuit) caused by the re-deposition of the first etch by-products may not occur.

Further, during the anisotropic-etching process, the sidewall of the preliminary upper electrode 126a may not be exposed, but the top surface of the preliminary upper electrode 126a may be exposed. Thus, an exposed area of the preliminary upper electrode 126a may be reduced so an amount of second etch by-products having conductivity, which are generated by etching a portion of the preliminary upper electrode 126a during the anisotropic-etching process, may be reduced. As a result, an electrical failure (e.g., electrical short-circuit) that may be caused by the second conductive etch by-products being re-deposited on a sidewall of an etched portion of the MTJ layer 114 may be reduced or prevented.

In some example embodiments, a portion of an upper edge of the preliminary mask structure 128 may be etched by the anisotropic-etching process, and thus, a mask structure 128a including an upper electrode 126b and a sidewall capping pattern 122b may be formed. The mask structure 128a may have an upper width and a lower width that is larger than the upper width (as also depicted in FIG. 1A).

In some example embodiments, the mask structure 128a may include a lower portion 128aL (FIG. 1C) having the constant or substantially constant width and an upper portion 128aU (FIG. 1C) having a width that is less than the width of the lower portion 128aL. The width of the upper portion 128aU of the mask structure 128a may gradually decrease as the distance increases from the substrate 100.

In other example embodiments, the mask structure 128a may have a width that gradually decreases in a direction from a bottom surface to a top surface of the mask structure 128a.

In some example embodiments, the upper electrode 126b may have a lower width and an upper width that is greater than the lower width, as also depicted in FIG. 1A.

In other example embodiments, the upper electrode 126b may include a lower portion 126bL (FIG. 1C) having the constant or substantially constant width and an upper portion 126bU (FIG. 1C) having a width that is greater than the width of the lower portion 126bL. The width of the upper portion 126bU of the upper electrode 126b may gradually increase as the distance increases from the substrate 100.

In other example embodiments, the upper electrode 126b may have a width that gradually increases in a direction from a bottom surface to a top surface of the upper electrode 126b.

In some example embodiments, the sidewall capping pattern 122b may have a lower width and an upper width that is less than the lower width, as also depicted in FIG. 7.

In other example embodiments, the sidewall capping pattern 122b may include a lower portion 122bL having the constant or substantially constant width and an upper portion 122bU having a width that is less than the width of the lower portion 122bL. The width of the upper portion 122bU of sidewall capping pattern 122b may gradually decrease as the distance increases from the substrate 100.

In other example embodiments, the sidewall capping pattern 122b may have a width that gradually decreases in a direction from a bottom surface to a top surface of the sidewall capping pattern 122b.

On the top surface of the mask structure 128a, an exposed area of the upper electrode 126b as viewed in a plan view may be greater than a projected area of the sidewall capping pattern 122b as viewed in the plan view. In some example embodiments, the top surface of the upper electrode 126b, which may correspond to the top surface of the mask structure 128a, may be exposed, and a side surface of the sidewall capping pattern 122b, which may correspond to a sidewall of the mask structure 128a, may also be exposed.

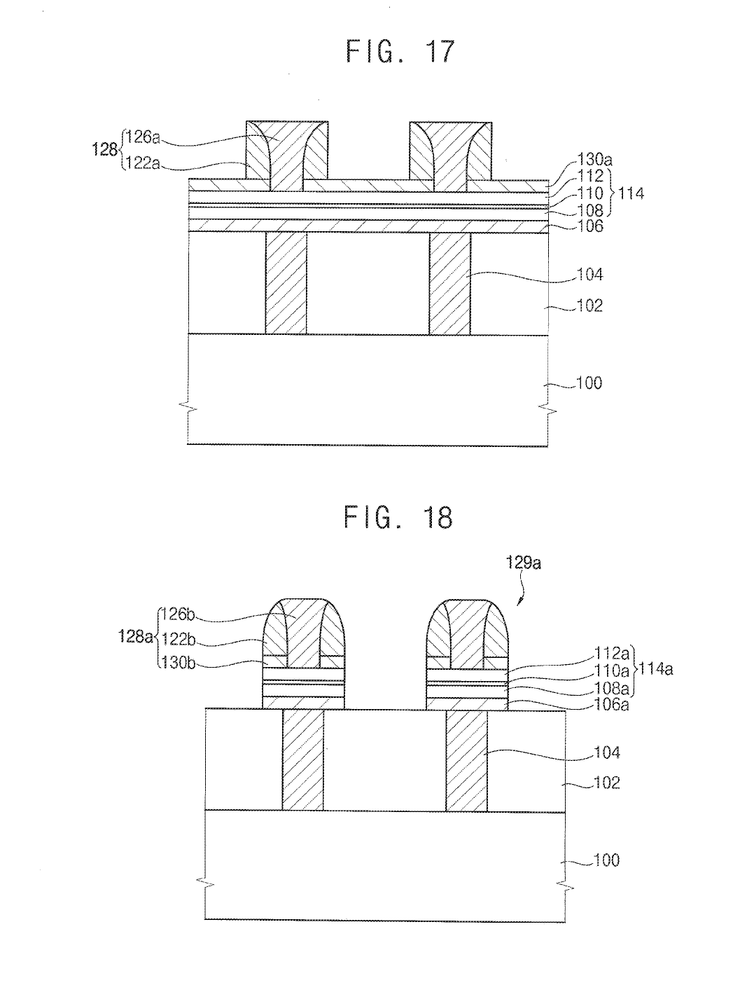

FIGS. 13 through 18 are sectional views depicting stages of a method of manufacturing a magnetoresistive memory device according to example embodiments of the inventive concepts. An example embodiment of FIGS. 13 through 18 may include processes similar to or substantially the same as those described with reference to FIGS. 2 through 12 except for depositing additional layers.

Referring to FIG. 13, an interlayer insulating layer 102 may be formed on a substrate 100 using a well-known technique, and a contact plug 104 may be formed using a well-known technique to pass through the interlayer insulating layer 102 and may be in contact with the substrate 100.

A lower electrode layer 106, a MTJ layer 114, an etch-stop layer 130, and a mold layer 116 may be sequentially formed on the interlayer insulating layer 102 and the contact plug 104 using a well-known technique.

In some example embodiments, the etch-stop layer 130 may include an insulating material. For example, the etch-stop layer 130 may include silicon nitride or silicon oxynitride. The etch-stop layer 130 may formed to have a thin thickness ranging from about 10 Å to about 300 Å so to be easily etched in a subsequent process.

Referring to FIG. 14, a photoresist pattern (not shown) that includes a hole (e.g., a plurality of holes) therein may be formed on the mold layer 116 of FIG. 13. A mold pattern 116a may be formed by anisotropically etching the mold layer 116 using the photoresist pattern as an etch mask. Next, the photoresist pattern may be removed. The mold pattern 116a may include a first hole 120a formed in the mold pattern 116a. A plurality of first holes 120a may be formed. The top surface of the MTJ layer 114 may be exposed by the first hole 120a.

Referring to FIG. 15, a capping layer may be conformally formed in a well-known manner on an inner surface of the first hole 120a and on a top surface of the mold pattern 116a. The formation process of the capping layer may be the same or similar to that described with reference to FIG. 6.

As the capping layer and the etch-stop layer 130 are anisotropically etched, a preliminary sidewall capping pattern 122a may be formed on a sidewall of the mold pattern 116a and a preliminary etch-stop pattern 130a may be formed under the mold pattern 116a and the preliminary sidewall capping pattern 122a. Thus, a second hole 124 may be formed to have a width that is smaller than a width of the first hole 120a due to the preliminary sidewall capping pattern 122a on the sidewalls of the first hole 120a and the preliminary etch-stop pattern 130a. A plurality of second holes 124 may be formed. The top surface of the MTJ layer 114 may be exposed by the second hole 124.

In some example embodiments, the preliminary sidewall capping pattern 122a and the preliminary etch-stop pattern 130a may include a same material, for example, silicon nitride.

Referring to FIG. 16, an upper electrode layer may be formed on the top surface of the mold pattern 116a, a surface of the preliminary sidewall capping pattern 122a, a surface of the preliminary etch-stop pattern 130a, and the top surface of the MTJ layer 114 to fill the second hole 124, and then the upper electrode layer may be planarized to expose the top surface of the mold pattern 116a. Thus, a preliminary mask structure 128 that includes a preliminary upper electrode 126a and the preliminary sidewall capping pattern 122a may be formed. The preliminary upper electrode 126a may directly contact the top surface of the MTJ layer 114.

The processes described above may be substantially the same as those described with reference to FIGS. 8 and 9.

Referring to FIG. 17, the mold pattern 116a may be removed to expose the preliminary etch-stop pattern 130a. The removal of the mold pattern 116a may be performed by an isotropic-etching process. The MTJ layer 114 may be covered with the preliminary etch-stop pattern 130a and the preliminary mask structure 128.

Referring to FIG. 18, the exposed preliminary etch-stop pattern 130a may be anisotropically etched using the preliminary mask structure 128 as an etch mask to form an etch-stop pattern 130b, and then the MTJ layer 114 and the lower electrode layer 106 may be sequentially anisotropically etched. Thus, a variable-resistance structure 129a that includes a lower electrode 106a may be in contact with the contact plug 104, a MTJ structure 114a, an upper electrode 126b, a sidewall capping pattern 122b, and the etch-stop pattern 130b may be formed. Thus, the etch-stop pattern 130b may be formed under the sidewall capping pattern 122b. The etch-stop pattern 130b may be formed to surround the upper electrode 126b together with the sidewall capping pattern 122b. Thus, the etch-stop pattern 130b may serve as a portion of a sidewall capping pattern 122b of a mask structure 128a. For example, the mask structure 128a may include the upper electrode 126b, the sidewall capping pattern 122b, and the etch-stop pattern 130b.

In some example embodiments, in the case in which the sidewall capping pattern 122b and the etch-stop pattern 130b include a same material, the variable-resistance structure 129a of FIG. 18 may be the same as the variable-resistance structure 129 illustrated in FIGS. 1A and 1B.

FIG. 19 is a sectional view depicting a magnetoresistive memory device according to example embodiments of the inventive concepts.

In the present example embodiments, the magnetoresistive memory device may include elements or configurations that are similar to or the same as those described with reference to FIGS. 1A and 1B except for a barrier pattern 140 may disposed between a MTJ structure 114a and a mask structure 128a in the configuration of present example embodiments.

Referring to FIG. 19, the magnetoresistive memory device may include an interlayer insulating layer 102 and a contact plug 104 passing through the interlayer insulating layer 102 that is in contact with the substrate 100. The magnetoresistive memory device may further include a variable-resistance structure 129b disposed on the interlayer insulating layer 102. The variable-resistance structure 129b may contact a top surface of the contact plug 104. The variable-resistance structure 129b may include a lower electrode 106a, the MTJ structure 114a, the barrier pattern 140, the upper electrode 126b and a sidewall capping pattern 122b.

The lower electrode 106a and the MTJ structure 114a may be the same as those described with reference to FIGS. 1A and 1B. A mask structure 128a including the upper electrode 126b and the sidewall capping pattern 122b may be the same as those described with reference to FIGS. 1A and 1B.

As the mask structure 128a is formed on the barrier pattern 140, a top surface of the barrier pattern 140 may be larger than a bottom surface of the upper electrode 126b. For example, the bottom surface of the upper electrode 126b may be positioned on a central portion of the top surface of the barrier pattern 140.

The barrier pattern 140 may include titanium, titanium nitride, tantalum and/or tantalum nitride.

The magnetoresistive memory device may be formed by following processes.

An interlayer insulating layer 102 may be formed in a well-known manner on the substrate 100, and then a contact plug 104 may be formed in a well-known manner to pass through the interlayer insulating layer 102 to be in contact with the substrate 100. A lower electrode layer, a MTJ layer, a barrier layer and a mold layer may be sequentially formed on the interlayer insulating layer 102 and the contact plug 104. The interlayer insulating layer 102, the contact plug 104, the lower electrode layer, the MTJ layer and the mold layer may be the same as those described with reference with FIG. 2. However, the barrier layer may be additionally formed after forming the MTJ layer.

A mold pattern may be formed on the barrier layer by the same process as that described with reference to FIGS. 3 and 4. The barrier layer may be exposed by a hole (e.g., a first hole) in the mold pattern. In a following process, an upper electrode and a sidewall capping pattern formed in the first hole of the mold pattern may be in contact with the barrier layer.

Thereafter, the magnetoresistive memory device shown in FIG. 19 may be formed by performing the same processes as those described with reference to FIGS. 5 to 12.

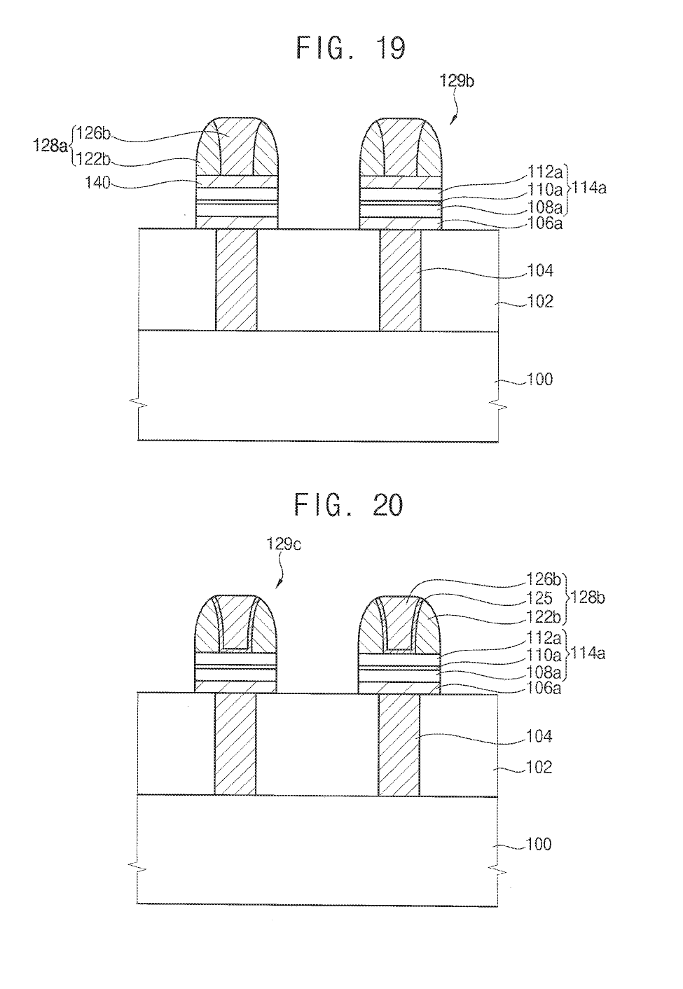

FIG. 20 is a sectional view depicting a magnetoresistive memory device according to example embodiments of the inventive concepts. In an embodiment, the magnetoresistive memory device may include elements or configurations that are similar to or the same as those described with reference to FIGS. 1A and 1B, except for a barrier pattern 125 extending along a sidewall and a bottom surface of an upper electrode 126b in the present example embodiment.

Referring to FIG. 20, the magnetoresistive memory device may include an interlayer insulating layer 102 and a contact plug 104 passing through the interlayer insulating layer 102 and in contact with the substrate 100. Further, magnetoresistive memory device may include a variable-resistance structure 129c disposed on the insulating layer. The variable-resistance structure 129c may be in contact with a top surface of the contact plug 104. The variable-resistance structure 129c may include a lower electrode 106a, the MTJ structure 114a, the upper electrode 126b, the barrier pattern 125, and a sidewall capping pattern 122b. A mask structure 128b may include the upper electrode 126b, the barrier pattern 125 and the sidewall capping pattern 122b.

The lower electrode 106a and the MTJ structure 114a may be the same as those described with reference to FIGS. 1A and 1B. Likewise, the upper electrode 126b and the sidewall capping pattern 122b may be the same as those described with reference to FIGS. 1A and 1B.

The barrier pattern 125 may be disposed on a sidewall and a bottom surface of the upper electrode 126b. That is, the barrier pattern 125 may extend along the sidewall and the bottom surface of the upper electrode 126b. The barrier pattern 125 may be interposed between the upper electrode 126b and the sidewall capping pattern 122b and between the upper electrode 126b and the MTJ structure 114a.

The barrier pattern 125 may include titanium, titanium nitride, tantalum and/or tantalum nitride.

The magnetoresistive memory device may be manufactured by the following processes.

The same or similar processes as those described with reference to FIG. 2 through 7 may be performed, and then, a barrier layer may be conformally formed on a top surface of a mold pattern 116a, a surface of a preliminary sidewall capping pattern 122a and a top surface of a MTJ layer 114.

An upper electrode layer may be formed on the barrier layer to fill a hole (e.g., a third hole) defined by the barrier layer. The process of forming the upper electrode layer may be the same as or similar to that described with reference to FIG. 8.

Since the upper electrode layer is formed on the barrier layer, a barrier pattern 125 may be formed along a sidewall and a bottom surface of an upper electrode to be formed in the following process.

As a result, the magnetoresistive memory device shown in FIG. 20 may be formed by performing the same processes as those described with reference to FIGS. 9 through 12.

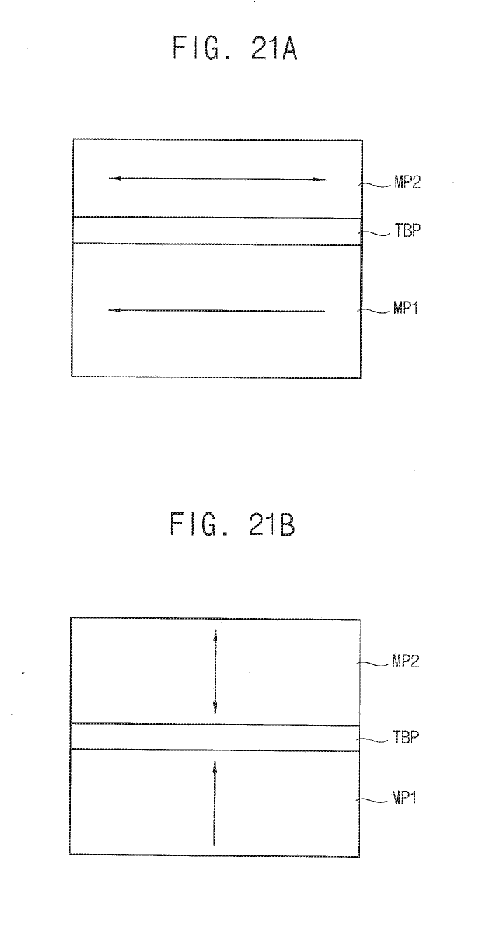

FIGS. 21A and 21B are conceptual diagrams depicting magnetic tunnel junction patterns according to some embodiments of the inventive concepts.

The MTJ structure 114a described in connection with FIGS. 1A-1C may include a first magnetic pattern MP1, a tunnel barrier pattern TBP and a second magnetic pattern MP2, as depicted in FIGS. 21A and 21B. One of the first or second magnetic patterns MP1 and MP2 may correspond to a free magnetic pattern of a magnetic tunnel junction, and the other of the first and second magnetic patterns MP1 and MP2 may correspond to a pinned or fixed magnetic pattern (i.e., a reference pattern) of the magnetic tunnel junction. For the purpose of ease and convenience in explanation, the first magnetic pattern MP1 will be described as the pinned magnetic pattern and the second magnetic pattern MP2 will be described as the free magnetic pattern. In some embodiments, however, the first magnetic pattern MP1 may be the free magnetic pattern and the second magnetic pattern MP2 may be the pinned magnetic pattern. A value of electrical resistance of the MTJ structure 114a may be determined based on the magnetization directions of the free magnetic pattern and the pinned magnetic pattern. For example, the value of electrical resistance of the MTJ structure 114a if the magnetization directions of the free and pinned magnetic patterns are anti-parallel to each other may be much greater than the value of electrical resistance of the MTJ structure 114a if the magnetization directions of the free and pinned patterns are parallel to each other. As a result, the value of electrical resistance of the MTJ structure 114a may be adjusted by changing the magnetization direction of the free magnetic pattern. Changing the magnetization direction of the free magnetic patterns may be used as a data-storing principle of the magnetic memory device according to some embodiments of the inventive concepts.

Referring to FIG. 21A, the magnetization directions of the first and second magnetic patterns MP1 and MP2 may be substantially parallel to a top surface of the tunnel barrier pattern TBP, and thus the first and second magnetic patterns MP1 and MP2 may form a horizontal magnetization structure. That is, the first and second magnetic patterns MP1 and MP2 may have a horizontal magnetization anisotropy. In this case, the first magnetic pattern MP1 may include a layer including an anti-ferromagnetic material and a layer including a ferromagnetic material. In some embodiments, the layer including the anti-ferromagnetic material may include at least one of PtMn, IrMn, MnO, MnS, MnTe, MnF₂, FeCl₂, FeO, CoCl₂, CoO, NiCl₂, NiO or Cr. In some embodiments, the layer of the first magnetic pattern MP1 that includes the anti-ferromagnetic material may include at least one precious metal. The precious metal may include ruthenium (Ru), rhodium (Rh), palladium (Pd), osmium (Os), iridium (Ir), platinum (Pt), gold (Au) or silver (Ag). The layer of the first magnetic pattern MP1 that includes the ferromagnetic material may include at least one of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO or Y₃Fe₅O₁₂.

The second magnetic pattern MP2 may include a material that has a changeable magnetization direction. The second magnetic pattern MP2 may include a ferromagnetic material. For example, the second magnetic pattern MP2 may include at least one of FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO or Y₃Fe₅O₁₂.

The second magnetic pattern MP2 may include a plurality of layers. For example, the second magnetic pattern MP2 may include a plurality of ferromagnetic layers and a non-magnetic material layer that are disposed between the ferromagnetic layers. In this case, the ferromagnetic layers and the non-magnetic material layer may form a synthetic antiferromagnetic layer. The synthetic antiferromagnetic may reduce a critical current density of the magnetic memory device and may also improve thermal stability of the magnetic memory device.

The tunnel barrier pattern TBP may include at least one of magnetic oxide (MgO), titanium oxide (TiO), aluminum oxide (AlO), magnesium-zinc oxide (MgZnO), magnesium-boron oxide (MgBO), titanium nitride (TiN) or vanadium nitride (VN). In some embodiments, the tunnel barrier pattern TBP may be a single layer formed of magnesium oxide (MgO). Alternatively, the tunnel barrier pattern TBP may include a plurality of layers. The tunnel barrier pattern TBP may be formed using a CVD process.

Referring to FIG. 21B, the magnetization directions of the first and second magnetic patterns MP1 and MP2 may be substantially perpendicular to the top surface of the tunnel barrier pattern TBP, and thus the first and second magnetic patterns MP1 and MP2 may form a perpendicular magnetization structure. That is, the first and second magnetic patterns MP1 and MP2 may have a vertical magnetization anisotropy. In this case, each of the first and second magnetic patterns MP1 and MP2 may include at least one of a material having a L1₀ crystal structure, a material having a hexagonal close packed (HCP) crystal structure or an amorphous rare-earth transition metal (RE-TM) alloy. In some embodiments, each of the first and second magnetic patterns MP1 and MP2 may include at least one of Fe₅₀Pt₅₀ having a L1₀ crystal structure, Fe₅₀Pd₅₀ having a L1₀ crystal structure, Co₅₀Pt₅₀ having a L1₀ crystal structure, Co₅₀Pd₅₀ having a L1₀ crystal structure or Fe₅₀Ni₅₀ having a L1₀ crystal structure. In some embodiments, each of the first and second magnetic patterns MP1 and MP2 may include a CoPt disordered alloy or a Co₃Pt ordered alloy that has a HCP crystal structure and a platinum content of about 10 at % to about 45 at %. In some embodiments, each of the first and second magnetic patterns MP1 and MP2 may include at least one amorphous RE-TM alloy that includes at least one element selected from iron (Fe), cobalt (Co), and nickel (Ni) and at least one element selected from terbium (Tb), dysprosium (Dy), and gadolinium (Gd) corresponding to rare-earth metals.

The first and second magnetic patterns MP1 and MP2 may include a material having interface perpendicular magnetic anisotropy (i-PMA). The interface perpendicular magnetic anisotropy may provide that a magnetic layer having an intrinsic horizontal magnetization property has a perpendicular magnetization direction caused by an influence of an interface between the magnetic layer and another that is adjacent layer magnetic layer. Here, the intrinsic horizontal magnetization property may provide that a magnetic layer has a magnetization direction that is substantially parallel to the widest surface of the magnetic layer if an external factor does not exist. For example, if the magnetic layer having the intrinsic horizontal magnetization property is formed on a substrate and an external factor does not exist, the magnetization direction of the magnetic layer may be substantially parallel to a top surface of the substrate.

Each of the first and second magnetic patterns MP1 and MP2 may, for example, include at least one of cobalt (Co), iron (Fe) or nickel (Ni). Additionally, each of the first and second magnetic patterns MP1 and MP2 may further include at least one element selected from non-magnetic materials that include boron (B), zinc (Zn), aluminum (Al), titanium (Ti), ruthenium (Ru), tantalum (Ta), silicon (Si), silver (Ag), gold (Au), copper (Cu), carbon (C) and nitrogen (N). For example, each of the first and second magnetic patterns MP1 and MP2 may include CoFe or NiFe, and may further include boron (B). Moreover, to reduce saturation magnetization of the first and second magnetic patterns MP1 and MP2, each of the first and second magnetic patterns MP1 and MP2 may further include at least one of titanium (Ti), aluminum (Al), silicon (Si), magnesium (Mg) or tantalum (Ta).

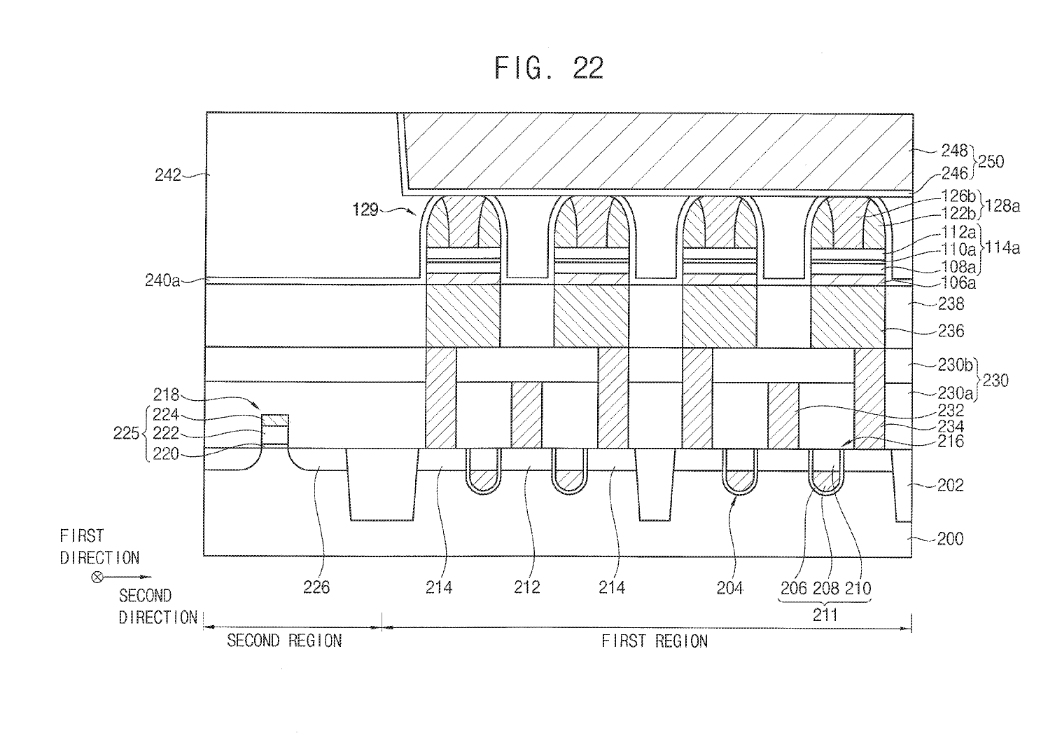

FIG. 22 is a sectional view depicting a magnetoresistive memory device according to example embodiments of the inventive concepts.

Referring to FIG. 22, a substrate 200 including a first region and a second region may be provided. The first region may be a cell region where one or more of the magnetoresistive memory cells are formed. The second region may be a peripheral circuit region where one or more peripheral circuits are formed and may be disposed around the first region.

The substrate 200 of the first and second regions may include a field region and an active region defined by the field region.

In the first region, a plurality of the active regions, each of which has an isolated island-type shape, may be regularly arranged. The field region may include a device isolation layer 202. At least one of first transistors 216 may be provided on each active region. For example, two of the first transistors 216, each of which includes a first gate 211, may be formed on each of the active regions. A first source region 212 shared by the two of the first transistors 216 may be provided at central portion of each of the active regions. That is, the first source region 212 may be a common source region of the two of the first transistors 216. First drain regions 214 may be provided at opposite edge portions of each of the active region. The first transistor 216 may be a buried-gate-type transistor formed in a trench 204 in the substrate 200. The first gate 211 may include a first gate insulating pattern 206, a first gate electrode 208, and a first hard mask pattern 210 that are disposed in trench 204. The first gate 211 may extend in a first direction and may be a line-shaped pattern.

In some example embodiments, the first transistor 216 may be a planar-type transistor in which the first gate 211 is formed on a surface of the substrate 200.

Source lines 232 may be disposed on the substrate 200 to extend in the first direction and may be in contact with the first source regions 212. Each of the source lines 232 may include, for example, a metal, such as tungsten, titanium, tantalum or iron, and/or a metal nitride, such as titanium nitride or tantalum nitride.

A second transistor 218 forming the peripheral circuits may also be disposed on the substrate 200 of the second region. The second transistor 218 may be a planar-type transistor. For example, the second transistor 218 may include a second gate 225 and second source/drain regions 226. The second gate may include a second gate insulating pattern 220, a second gate electrode 222 and a second hard mask pattern 224.

An interlayer insulating layer 230 may be disposed on the substrate 200 of the first and second regions. The first interlayer insulating layer 230 may entirely cover the source lines 232 and the first and second transistors 216 and 218. The first interlayer insulating layer 230 may have a top surface that is planar. The top surface of the first interlayer insulating layer 230 may be positioned at a level that is higher than a top surface of each of the first source lines 232. As an example, the interlayer insulating layer 230 may include a first lower interlayer insulating layer 230a and a second lower interlayer insulating layer 230b. The source lines 232 may pass through the lower interlayer insulating layer 230a.

Contact plugs 234 may be disposed on the substrate 200 of the first region. The contact plugs 234 may pass through the first interlayer insulating layer 230 and are in contact with the first drain regions 214. The contact plugs 234 may each have a top surface that is higher than a top surface of each of the source lines 232.

Pad patterns 236 may be respectively disposed on the contact plugs 234. An insulating pattern 238 may be disposed between adjacent ones of the pad patterns 236. The pad patterns 236 may be provided for a direct contact between the contact plugs 234 and variable-resistance structures 129. Thus, in a case in which the contact plugs 234 and the variable-resistance structures 129 are directly in contact with each other, the pad patterns 236 may not be provided.

The variable-resistance structures 129 may be respectively disposed on the pad patterns 236.

In some example embodiments, each of the variable-resistance structures 129 may have the same configurations and materials as that described with reference to FIGS. 1A-1C. In other example embodiments, each of the variable-resistance structures 129 may have the same configurations and materials as that described with reference to FIG. 19 or that described with reference to FIG. 20.

The variable-resistance structures 129 may each include a lower electrode 106a, a MTJ structure 114a, an upper electrode 126a and a sidewall capping pattern 122b. As each variable-resistance structure 129 includes an upper electrode 126b and a sidewall capping pattern 122b that are provided as a mask structure 128a, a short circuit between first and second magnetic patterns 108a and 112a of the MTJ structure 114a may be reduced or prevented.

An insulating capping pattern 240a may be disposed on a top surface of the insulating pattern 238 and a sidewall of the variable-resistance structure 129. The insulating capping pattern 240a may not be disposed on top surfaces of the variable-resistance structures 129. The insulating capping pattern 240a may include, for example, silicon nitride.

An upper interlayer insulating layer 242 may be disposed on the insulating capping pattern 240a to cover at least a portion of each of the variable-resistance structures 129. The upper interlayer insulating layer 242 may include, for example, silicon oxide.

A bit line 250 may be provided to be in contact with the variable-resistance structures 129. For example, the bit line 250 may partially pass through the upper interlayer insulating layer 242 to contact the top surfaces of the variable-resistance structures 129. The bit line 250 is disposed in the upper interlayer insulating layer 242. The bit line 250 may be electrically connected to a plurality of the upper electrodes 126a and may extend in a second direction perpendicular to the first direction. A plurality of bit lines 250 may be formed. For example, a plurality of the bit lines 250 may be arranged to be parallel or substantially parallel to each other in the first direction. The bit line 250 may be an interconnection layer.

In some example embodiments, the bit line 250 may be disposed on upper interlayer insulating layer 242 and via plugs may further be disposed in the upper interlayer insulating layer 242 to connect the bit line 250 with the upper electrodes 126b of the variable-resistance structures 129.

The bit line 250 may include a barrier metal pattern 246 and a metal pattern 248 that are sequentially stacked. The barrier metal pattern 246 may include titanium, titanium nitride, tantalum and/or tantalum nitride. The metal pattern 248 may include copper, tungsten or aluminum.

A top surface of the bit line 250 and a top surface of the upper interlayer insulating layer 242 may be substantially planar with each other. In an example embodiment, an interlayer insulating layer may be further provided to cover the upper interlayer insulating layer 242 and the bit line 250.

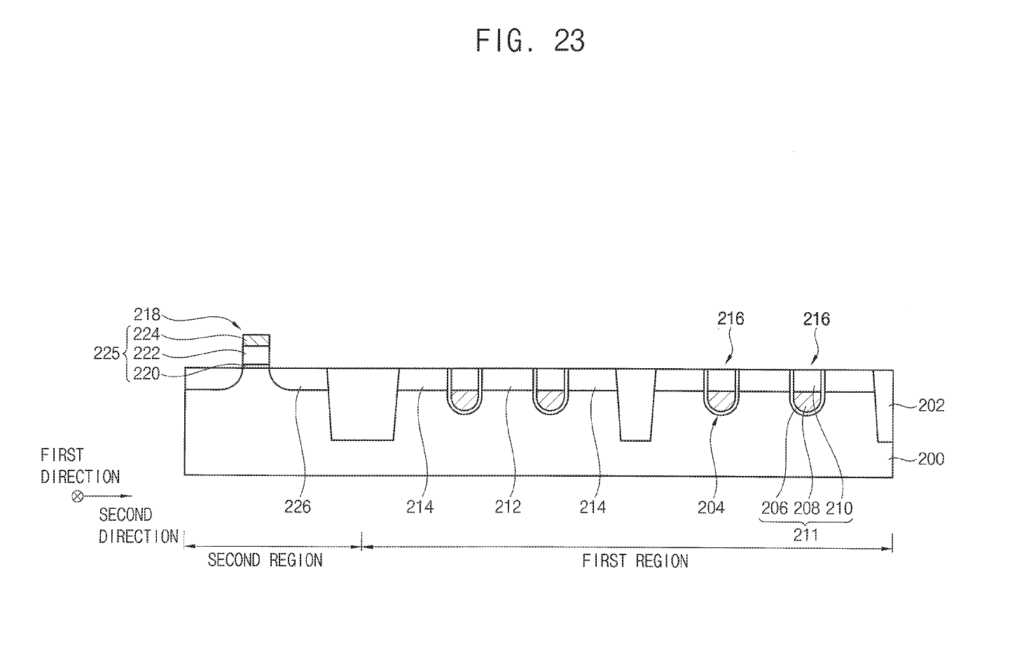

FIGS. 23 through 29 are sectional views depicting stages of a method of a magnetoresistive memory device according to example embodiments of the inventive concepts.

Referring to FIG. 23, a substrate 200 may include a first region where one or more magnetoresistive memory cells may be formed and a second region where one or more peripheral circuits may be formed.

A device isolation layer 202 may be formed in the substrate 200 to define an active region and field region in the substrate 200. The device isolation layer 202 may be formed through a shallow trench isolation (STI) process. The active region may have an isolated island-type shape. A plurality of active regions may be regularly arranged.

First transistors 216 may be formed in the first region of the substrate 200. For example, two of the first transistors 216 may be formed on each of the active regions. The first transistors 216 may be buried-gate-type transistors. For the formation of the first transistors 216, a mask pattern may be formed on the substrate 200, and then the substrate 200 may be etched using the mask pattern as an etch mask to form a trench 204 that extends in a first direction with a line-type shape. Two of the trenches 204 may be formed in the active region. A first gate 211 including a first gate insulating pattern 206, a first gate electrode 208, and a first hard mask pattern 210 may be formed in the trench 204. The first gate insulating pattern 206, the first gate electrode 208 and the first hard mask pattern 210 may be sequentially formed in the trench 204. Further, first source regions 212 and first drain regions 214 may be formed in the active regions by injecting impurities into each active region at both sides of each of the two of the first gates 211. Each of the first source regions 212 may function as a common source region of two of the first transistors 216. That is, each of the first source regions 212 may be shared by two of the first transistors 216.

Although the first transistors 216 are described as the buried-gate-type transistors in the present embodiment, the inventive concepts are not limited thereto. For example, the first transistors 216 may alternatively be planar-type transistors.

Meanwhile, a second transistor 218 may be formed in the second region of the substrate 200. The second transistor 218 may form peripheral circuits. For example, the second transistor 218 may be a planar-type transistor. For the formation of the second transistor 218, the second gate insulating layer, a second gate electrode layer, and a second hard mask 224 may be formed on the substrate 200. A second gate insulating pattern 220 and a second gate electrode 222 may be formed by respectively etching the second gate insulating layer and the second gate electrode layer using the second hard mask 224 on the second gate layer as an etch mask. Thus, a second gate 225 including the second gate insulating pattern 220, the second gate electrode 222 and the second hard mask pattern 224 may be formed. A second source/drain region 226 may be formed in the active region by injecting impurities in the active region at both sides of the second gate 225.

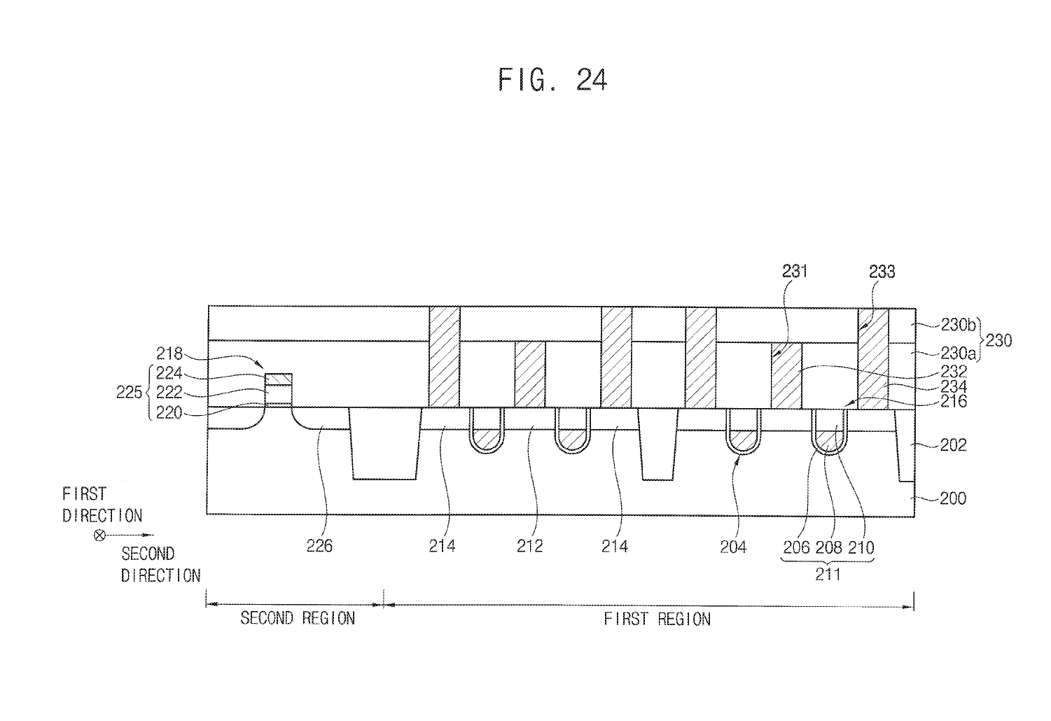

Referring to FIG. 24, a first lower interlayer insulating layer 230a may be formed on the substrate 200 of the first and second regions to cover the first and second transistors 216 and 218. After that, a planarization process may be performed in a well-known manner on the first lower interlayer insulating layer 230a so that the first lower interlayer insulating layer 230a has a planar top surface. The planarization process may include a chemical mechanical polishing (CMP) process or an etch-back process.

First openings 231 may be formed in the first lower interlayer insulating layer 230a by etching a portion of the first lower interlayer insulating layer 230a. The first openings 231 may expose the first source regions 212 and extend in the first direction. Source lines 232 that are in contact with the first source regions 232 may be respectively formed in the first openings 231. The formation of the source lines 232 may include forming a first conductive layer in the first openings 231 and planarizing the first conductive layer until the first lower interlayer insulating layer 230a is exposed. The source lines 232 may each include, for example, a metal, such as tungsten, titanium or tantalum, and/or a metal nitride, such as tungsten nitride, titanium nitride or tantalum nitride.

A second lower interlayer insulating layer 230b may be formed on the first lower interlayer insulating layer 230a and the source lines 232. Because the top surface of the first lower interlayer insulating layer 230a may be planar, a top surface of the second lower interlayer insulating layer 230b may also be planar. The first and second lower interlayer insulating layer 230a and 230b may be formed of silicon oxide.

Second openings 233 may be formed in the first region to pass through the first and second lower interlayer insulating layer 230a and 230b. The second openings 233 may respectively expose the first drain regions 214. Contact plugs 234 may be respectively formed in the second openings 233 to be in contact with the drain regions 214. The formation of the contact plugs 234 may include forming a second conductive layer in the second openings 233 and planarizing the second conductive layer until the second lower interlayer insulating layer 230b is exposed. The contact plugs 234 may each include, for example, a metal, such as tungsten, titanium or tantalum, and/or a metal nitride, such as tungsten nitride, titanium nitride or tantalum nitride.

Thus, a first interlayer insulating layer 230 including the first and second lower interlayer insulating layers 230a and 230b may be formed on the substrate 200 of the first region and the second region. In the first region, the contact plugs 234 and the source lines 232 may be formed in the first interlayer insulating layer 230. A top surface of each of the contact plugs 234 may be positioned at a level that is higher than that of each of the source lines 232.

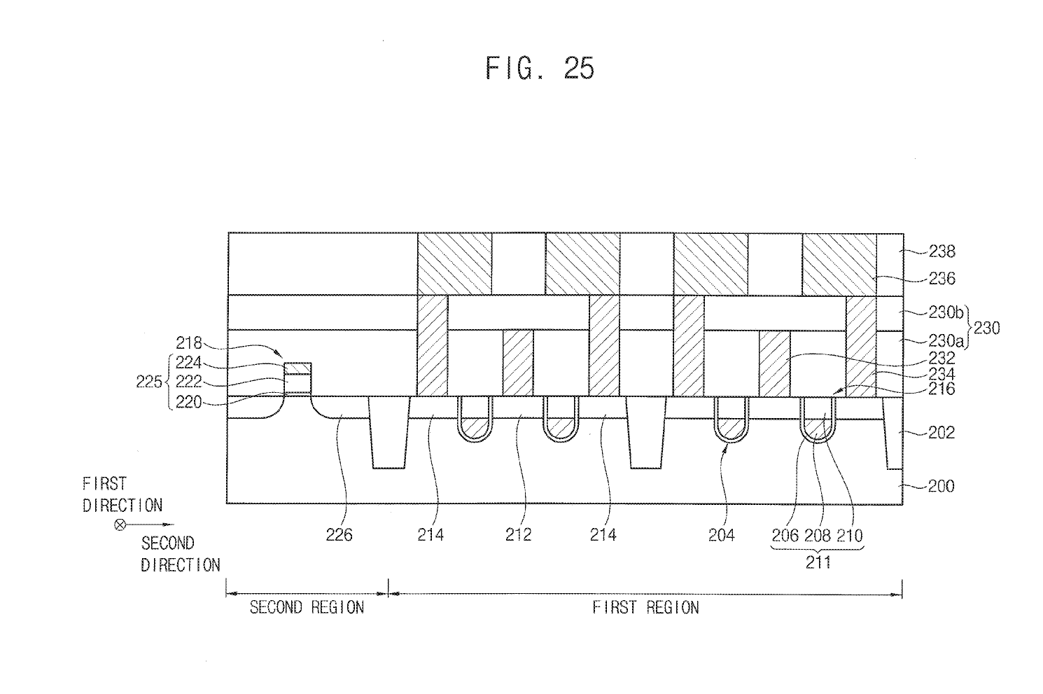

Referring to FIG. 25, a pad layer may be formed on the first interlayer insulating layer 230. The pad layer may include, for example, a metal, such as tungsten, titanium or tantalum, and/or a metal nitride, such as tungsten nitride, titanium nitride or tantalum nitride.

The pad layer may be etched to form pad patterns 236, each of which is in contact with respective ones of the contact plugs 234.

An insulating pattern 238 may be formed to fill spaces between adjacent ones of the pad patterns 236. The insulating pattern 238 may be formed of silicon nitride or silicon oxide.

In some example embodiments, the pad patterns 236 may be formed using a damascene process. For example, the formation of the insulating pattern 238 including grooves in which the pad patterns 238 are formed may precede formation of the pad patterns 236. Next, the pad layer may be formed in the grooves and then may be planarized to form the pad patterns 236.

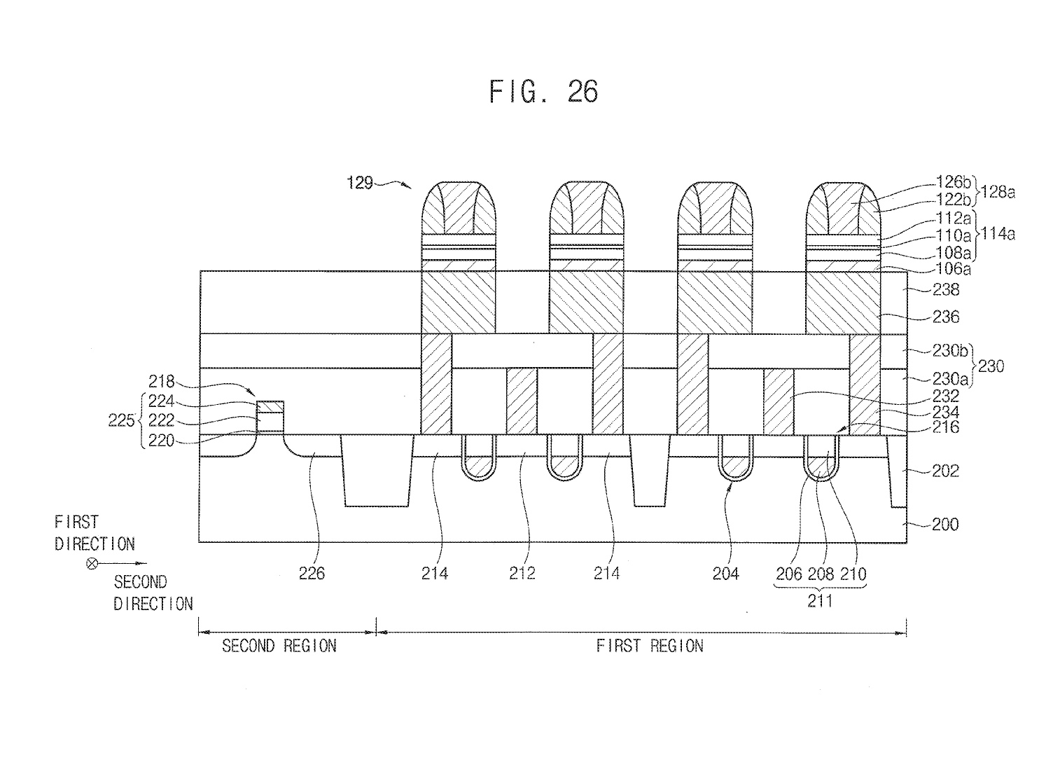

Referring to FIG. 26, variable-resistance structures 129 may be formed to be respectively in contact with the pad patterns 236. The variable-resistance structures 129 may each have an isolated island-type shape. Each variable-resistance structure 129 may include a lower electrode 106a, MTJ structure 114a, an upper electrode 126b and a sidewall capping pattern 122b. In one embodiment, an array of variable-resistance structures 129 may be formed in which the variable-resistance structures 129 are arranged in at least one row and at least one column.

In some example embodiments, each variable-resistance structure 129 may be formed to have the same configuration as that described with reference with FIGS. 1A-1C. In this case, each variable-resistance structure 129 may be formed using the same processes as those described with reference to FIG. 2 through 12.

In other embodiments, each variable-resistance structure 129 may be formed to have the same configuration as that described with reference with FIG. 18. In still other embodiments, each variable-resistance structure 129 may be formed to become the same as that described with reference with FIG. 19.

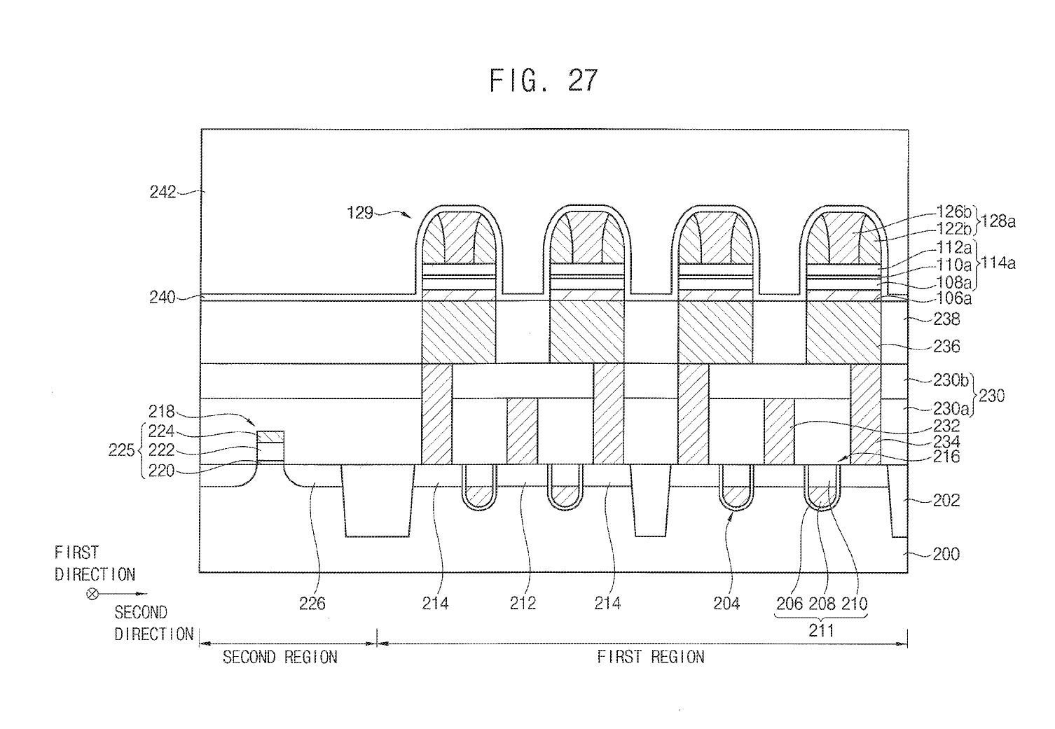

Referring to FIG. 27, an insulating capping layer 240 may be formed on the insulating pattern 238 and the variable-resistance structures 129. An upper interlayer insulating layer 242 may be formed on the insulating capping layer 240.

The upper interlayer insulating layer 242 may be conformally formed along surfaces of the variable-resistance structures 129, but may not fill spaces between the variable-resistance structures 129. The insulating capping layer 240 may include silicon nitride or silicon oxynitride.

The upper interlayer insulating layer 242 may include silicon oxide. In some example embodiments, a planarization process may further be performed on the upper interlayer insulating layer 242 so that the upper interlayer insulating layer 242 has a planar top surface.

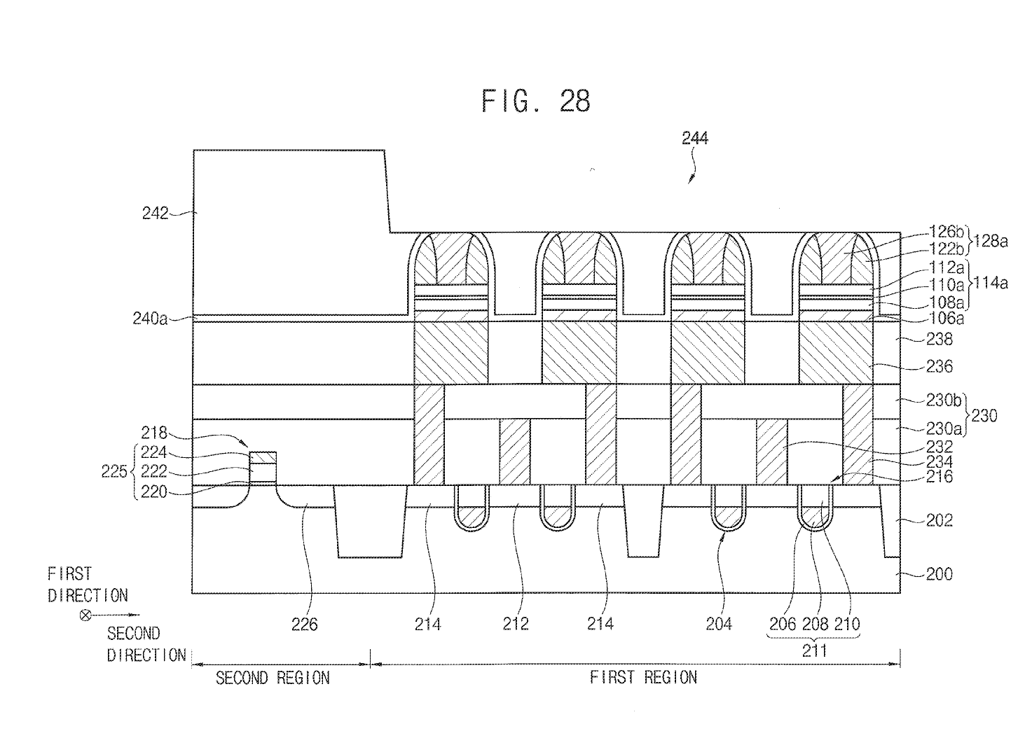

Referring to FIG. 28, a groove 244 for forming a bit line may be formed by etching a portion of the upper interlayer insulating layer 242 and a portion of the insulating capping layer 240. The groove 244 may extend in a second direction that is substantially perpendicular to the first direction. In some example embodiments, a plurality of grooves 244 may be formed.

In the etching process, a portion of the insulating capping layer 240 on the upper electrodes 126b may be removed, and thereby forming an insulating capping pattern 240a. Thus, the upper electrodes 126b may be exposed by the groove 244.

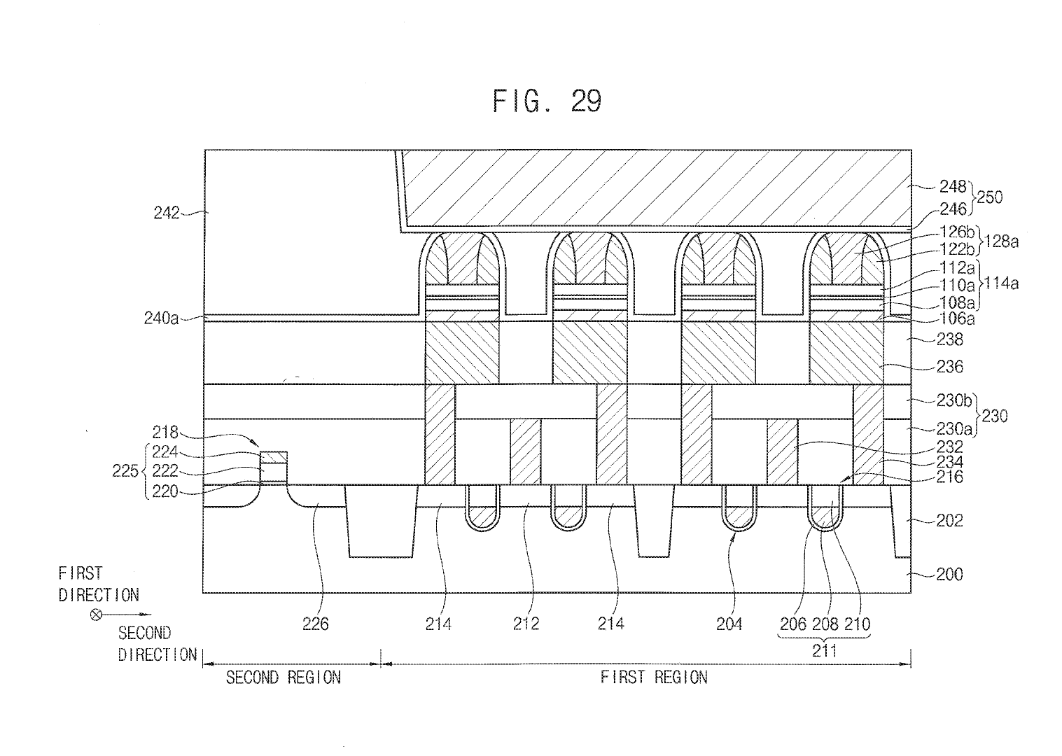

Referring to FIG. 29, a bit line 250 may be formed in the groove 244 and extend in the second direction. The formation of the bit line 250 may include forming a barrier metal layer on an inner surface of the groove 244, forming a metal layer on the barrier metal layer to fill the groove 244, and planarizing the metal layer and the barrier metal layer until the upper interlayer insulating layer 242 is exposed. The barrier metal layer may include titanium, titanium nitride, tantalum and/or tantalum nitride. The metal layer may include copper, tungsten or aluminum. Thus, the bit line 250 may include a barrier metal pattern 246 and a metal pattern 248. The bit line 250 may be in contact with the upper electrodes 126b. That is, the bit line 250 may be electrically connected to the upper electrodes 126b. The bit line 250 may be an interconnection layer. In some example embodiments, a via plug may further be formed in the upper interlayer insulating layer 242 to connect the bit line 250 on the upper interlayer insulating layer 242 with the upper electrodes 126b of the variable-resistance structures 129 without the formation of the groove 244. In other example embodiments, a plurality of the bit lines 250 may be respectively formed in the grooves 244 or on the upper interlayer insulating layer 242, and may be arranged in the first direction.

Although not illustrated in the drawings, an interlayer insulating layer may further be formed to cover the upper interlayer insulating layer 242 and the bit line 250.

At least one of the magnetoresistive memory devices according to afore-described example embodiments of the inventive concepts may be included in an electronic device, such as a mobile device, a memory card or computer.

FIG. 31 depicts an electronic device 3100 that comprises one or more integrated circuits (chips) comprising a semiconductor device that includes a magnetoresistive memory device according to embodiments disclosed herein. Electronic device 3100 may be used in, but not limited to, a computing device, a personal digital assistant (PDA), a laptop computer, a mobile computer, a web tablet, a wireless phone, a cell phone, a smart phone, a digital music player, or a wireline or wireless electronic device. The electronic device 3100 may comprise a controller 3110, an input/output device 3120 such as, but not limited to, a keypad, a keyboard, a display, or a touch-screen display, a memory 3130, and a wireless interface 3140 that are coupled to each other through a bus 3150. The controller 3110 may comprise, for example, at least one microprocessor, at least one digital signal process, at least one microcontroller, or the like. The memory 3130 may be configured to store a command code to be used by the controller 3110 or a user data. Electronic device 3100 and the various system components comprising a semiconductor device that includes a magnetoresistive memory device according to embodiments disclosed herein. The electronic device 3100 may use a wireless interface 3140 configured to transmit data to or receive data from a wireless communication network using a RF signal. The wireless interface 3140 may include, for example, an antenna, a wireless transceiver and so on. The electronic system 3100 may be used in a communication interface protocol of a communication system, such as, but not limited to, Code Division Multiple Access (CDMA), Global System for Mobile Communications (GSM), North American Digital Communications (NADC), Extended Time Division Multiple Access (E-TDMA), Wideband CDMA (WCDMA), CDMA2000, Wi-Fi, Municipal Wi-Fi (Muni Wi-Fi), Bluetooth, Digital Enhanced Cordless Telecommunications (DECT), Wireless Universal Serial Bus (Wireless USB), Fast low-latency access with seamless handoff Orthogonal Frequency Division Multiplexing (Flash-OFDM), IEEE 802.20, General Packet Radio Service (GPRS), iBurst, Wireless Broadband (WiBro), WiMAX, WiMAX-Advanced, Universal Mobile Telecommunication Service-Time Division Duplex (UMTS-TDD), High Speed Packet Access (HSPA), Evolution Data Optimized (EVDO), Long Term Evolution-Advanced (LTE-Advanced), Multichannel Multipoint Distribution Service (MMDS), and so forth.

In a method of manufacturing magnetoresistive memory device according to example embodiments of the inventive concepts, a MTJ layer and a lower electrode layer is etched using a mask structure including a preliminary upper electrode and a preliminary sidewall capping pattern on a sidewall of the preliminary upper electrode as an etch mask. Thus, when the MTJ layer is etched, an amount of etch by-products having conductivity generated from the preliminary upper electrode can be reduced. As result, a short-circuit failure of the MTJ structure caused by the etch by-products can be reduced or prevented.

While example embodiments of the inventive concepts have been particularly shown and described, it will be understood by one of ordinary skill in the art that variations in form and detail may be made therein without departing from the spirit and scope of the attached claims.

1. A magnetoresistive memory device, comprising:
a lower electrode on a substrate;
a magnetic tunnel junction (MTJ) structure on the lower electrode; and
a mask structure on the MTJ structure, the mask structure including an upper electrode and a sidewall capping pattern surrounding a sidewall of the upper electrode.

2. The magnetoresistive memory device of claim 1, wherein the upper electrode is in contact with a central portion of a top surface of the MTJ structure, and the sidewall capping pattern is in contact with an edge portion of the top surface of the MTJ structure.

3. The magnetoresistive memory device of claim 1, wherein the upper electrode has a lower width and an upper width that is greater than the lower width.

4. The magnetoresistive memory device of claim 1, wherein the upper electrode includes a lower portion having a substantially constant width and an upper portion having a width that gradually increases in a direction extending from a bottom surface of the upper electrode to a top surface of the upper electrode.

5. The magnetoresistive memory device of claim 1, wherein a maximum width of the upper electrode is substantially a same as or less than an upper width of the MTJ structure.

6. The magnetoresistive memory device of claim 1, wherein the sidewall capping pattern includes an insulating material.

7. The magnetoresistive memory device of claim 6, wherein the sidewall capping pattern includes silicon nitride, silicon oxynitride and/or silicon oxide.

8. The magnetoresistive memory device of claim 1, wherein the upper electrode includes tungsten, titanium, tantalum, iron, titanium nitride and/or tantalum nitride.

9. The magnetoresistive memory device of claim 1 wherein a bottom surface of the mask structure has substantially a same area as a top surface of the MTJ structure.

10. (canceled)

11. The magnetoresistive memory device of claim 1, a lower width of the mask structure is greater than an upper width of the mask structure.

12. The magnetoresistive memory device of claim 11, wherein the lower width is substantially constant and the upper width gradually decreases in a direction extending from a bottom surface of the mask structure to a top surface of the mask structure.

13. (canceled)

14. The magnetoresistive memory device of claim 1, wherein the MTJ structure includes a lower magnetic pattern, a tunnel barrier pattern and an upper magnetic pattern that are sequentially stacked.

15. The magnetoresistive memory device of claim 1, further comprising a barrier metal pattern interposed between the MTJ structure and the mask structure.

16. The magnetoresistive memory device of claim 1, further comprising a barrier metal pattern interposed between the upper electrode and the sidewall capping pattern, the barrier metal extending along a sidewall and a bottom surface of the upper electrode.

17. A magnetoresistive memory device, comprising:
an interlayer insulating layer on a substrate, the interlayer insulating layer including a conductive pattern therein;
a lower electrode on an interlayer insulating layer and contacting the conductive pattern;
an MTJ structure on the lower electrode;
a mask structure on the MTJ structure, the mask structure including an upper electrode and a sidewall capping pattern surrounding a sidewall of the upper electrode; and
an interconnection layer electrically connected to the upper electrode.

18. The magnetoresistive memory device of claim 17, further comprising a capping insulating layer disposed on the interlayer insulating layer, the lower electrode, the MTJ structure and the mask structure.

19-36. (canceled)

37. A magnetoresistive memory, comprising:
an array of lower electrodes on a substrate; and
a plurality of magnetoresistive memory cells, each magnetoresistive memory cell being arranged on a corresponding lower electrode, at least one magnetoresistive memory cell comprising a mask structure that includes an upper electrode of the magnetoresistive memory cell and a sidewall capping pattern on a sidewall of the upper electrode.

38. The magnetoresistive memory of claim 37, wherein each of the magnetoresistive memory cells further comprises a first magnetic layer, a tunnel barrier layer and a second magnetic layer that are sequentially stacked, the stack of the first magnetic layer, the tunnel barrier layer and the second magnetic layer comprising a width in a direction that is substantially perpendicular to a direction of the sequential stack, and
wherein a width of the mask structure is substantially equal to the width of the sequential stack.

39. The magnetoresistive memory of claim 37, wherein the sidewall capping pattern comprises a dielectric material.

40. (canceled)

41. The magnetoresistive memory of claim 40, wherein the upper electrode comprises a metal and/or a metal nitride.

42-56. (canceled)
